(19) United States
(12) Patent Application Publication
(10) Pub. No.: US 2025/0109233 A1
(43) Pub. Date: Apr. 3, 2025

(54) RESIN COMPOSITION, PREPREG, RESIN-COATED FILM, RESIN-COATED METAL FOIL, METAL-CLAD LAMINATE, AND WIRING BOARD

(71) Applicant: PANASONIC INTELLECTUAL PROPERTY MANAGEMENT CO., LTD., Osaka (JP)

(72) Inventors: Yasunori HOSHINO, Hyogo (JP); Mikio SATO, Kanagawa (JP); Yuki KITAI, Osaka (JP)

(73) Assignee: PANASONIC INTELLECTUAL PROPERTY MANAGEMENT CO., LTD., Osaka (JP)

(21) Appl. No.: 18/720,260

(22) PCT Filed: Oct. 13, 2022
(86) PCT No.: PCT/JP2022/038164

§ 371 Date: Dec. 16, 2024

(30) Foreign Application Priority Data
Dec. 24, 2021 (JP) 2021-210990

(51) Int. Cl. C08F 283/08; C08F 112/36; C08J 5/24; C08K 3/36; C08K 3/38; C08K 5/14; C08K 5/3492; C08L 79/08

(52) U.S. Cl. CPC C08F 283/08; C08F 112/36; C08J 5/24; C08K 3/36; C08K 3/38; C08K 5/14; C08K 5/34924; C08L 79/08; C08K 2003/385; C08K 2201/005; C08L 2203/16; C08L 2203/206; C08L 2205/03

(57) ABSTRACT

An aspect of the present invention relates to a resin composition containing a radical polymerizable compound (A), an inorganic filler (B) containing boron nitride (B-1) and silica (B-2), and a free radical compound (C) having at least one free radical group selected from the group consisting of structures represented by Formulas (1), (2), (3) and (4) in the molecule.

### TECHNICAL FIELD

The present invention relates to a resin composition, a prepreg, a film with resin, a metal foil with resin, a metal-clad laminate, and a wiring board.

### BACKGROUND ART

As the information processing quantity by various kinds of electronic equipment increases, mounting technologies such as high integration of semiconductor devices to be mounted, densification of wiring, and multilayering are progressing. In addition, wiring boards to be used in various kinds of electronic equipment are required to be, for example, high-frequency compatible wiring boards such as a millimeter-wave radar board for in-vehicle use. Wiring boards to be used in various kinds of electronic equipment are required to decrease the loss during signal transmission in order to increase the signal transmission speed, and this is especially required for high-frequency wiring boards. In order to meet this requirement, substrate materials for forming substrates of wiring boards to be used in various kinds of electronic equipment are required to have a low dielectric constant and a low dielectric loss tangent.

As such substrate materials, for example, a PPE-containing resin composition containing PPE (polyphenylene ether), a crosslinked curable compound, and a phosphaphenanthrene derivative has been reported (Patent Literature 1).

Meanwhile, electronic materials used in PA (power amplifier) boards of base stations and the like are required to have a high thermal conductivity in addition to a low dielectric constant and a low dielectric loss tangent. As one of the methods to improve the thermal conductivity of resin compositions, a technique in which boron nitride is used as an inorganic filler having a high thermal conductivity has been so far reported (Patent Literature 2).

The resin composition described in Patent Literature 1 cannot have a sufficient thermal conductivity. The boron nitride filler described in Patent Literature 2 certainly improves the thermal conductivity of resin compositions, but there is a problem in that the varnish viscosity necessary for board formation is not obtained when the resin composition is prepared in the form of a varnish in a case where the amount of added inorganic filler such as boron nitride is increased. Furthermore, it has also been found that thermal conductivity can be secured but problems arise in moldability when inorganic fillers such as boron nitride are highly filled.

### CITATION LIST

### Patent Literature

Patent Literature 1: JP 2015-67700 A
Patent Literature 2: JP 2013-241321 A

### SUMMARY OF INVENTION

The present invention has been made in view of the circumstances, and an object of thereof is to provide a resin composition that can provide a cured product exhibiting low dielectric properties (low dielectric constant) and a high thermal conductivity, exhibits excellent moldability, and can secure a varnish viscosity sufficient to maintain suitable fluidity when prepared in the form of a varnish. Another object of the present invention is to provide a prepreg, a film with resin, a metal foil with resin, a metal-clad laminate, and a wiring board which are obtained using the resin composition.

The present inventors have found out that the objects are achieved by the following configuration as a result of extensive studies, and have achieved the present invention by further conducting diligent studies.

In other words, a resin composition according to an aspect of the present invention contains a radical polymerizable compound (A), an inorganic filler (B) containing boron nitride (B-1) and silica (B-2), and a free radical compound (C) having at least one free radical group selected from the group consisting of structures represented by the following Formulas (1), (2), (3) and (4) in the molecule.

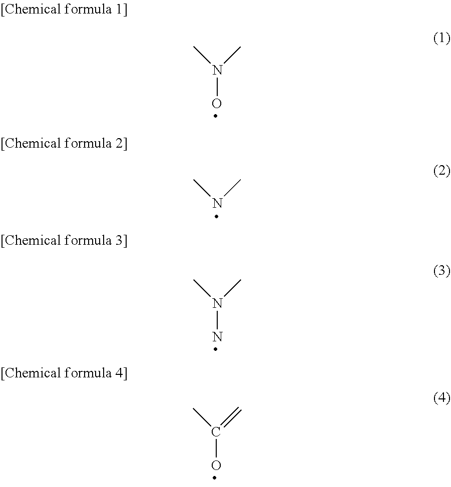

### BRIEF DESCRIPTION OF DRAWINGS

FIG. 1 is a schematic sectional view illustrating an example of a prepreg according to an embodiment of the present invention.

FIG. 2 is a schematic sectional view illustrating an example of a metal-clad laminate according to an embodiment of the present invention.

FIG. 3 is a schematic sectional view illustrating an example of a wiring board according to an embodiment of the present invention.

FIG. 4 is a schematic sectional view illustrating an example of a metal foil with resin according to an embodiment of the present invention.

FIG. 5 is a schematic sectional view illustrating an example of a film with resin according to an embodiment of the present invention.

### DESCRIPTION OF EMBODIMENTS

Hereinafter, embodiments according to the present invention will be specifically described, but the present invention is not limited thereto.

### [Resin Composition]

The resin composition according to an embodiment of the present invention contains a radical polymerizable compound (A), an inorganic filler (B) containing boron nitride (B-1) and silica (B-2), and a free radical compound (C) having at least one free radical group selected from the group consisting of structures represented by the following Formulas (1), (2), (3) and (4) in the molecule.

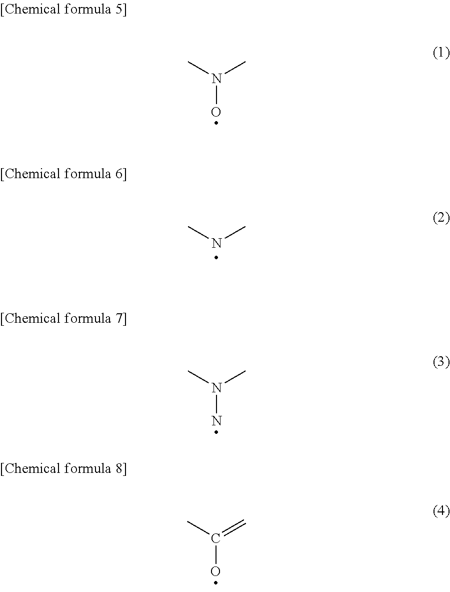

By the above configuration, it is possible to obtain a resin composition that can provide a cured product exhibiting low dielectric properties (particularly relative dielectric constant: Dk) and a high thermal conductivity, exhibits excellent moldability, and can secure a varnish viscosity sufficient to maintain suitable fluidity when prepared in the form of a varnish. This is considered to be because a resin composition exhibiting excellent moldability and handling properties can be obtained when inorganic fillers are highly filled as well by containing boron nitride, which has a high thermal conductivity, concurrently with silica and containing a free radical compound. The suitable varnish viscosity in the present embodiment means a viscosity that exhibits fluidity sufficient to fabricate a prepreg without any problems. According to the present invention, it is possible to provide a prepreg, a film with resin, a metal foil with resin, a metal-clad laminate, and a wiring board which exhibit excellent performance by using the resin composition.

First, each component constituting the resin composition of the present embodiment will be described.

### (Radical Polymerizable Compound (A))

The radical polymerizable compound (A) used in the present embodiment is not particularly limited as long as it is a compound that is radical polymerizable. Examples thereof include compounds having a reactive unsaturated group and compounds having a maleimide group.

More specific examples thereof include epoxy resins, polyphenylene ether resins, cyanate ester resins, phenol resins, benzoxazine resins, active ester resins, and resins having unsaturated groups. Examples of the resins having unsaturated groups include an acrylic resin, a methacrylic resin, a vinyl resin, an allyl resin, a propenyl resin, a maleimide resin, and a hydrocarbon-based resin having an unsaturated double bond.

Among these, the radical polymerizable compound (A) preferably includes at least one selected from the group consisting of a polyphenylene ether compound (A-1) having a carbon-carbon unsaturated double bond in the molecule, a hydrocarbon-based compound (A-2) having a carbon-carbon unsaturated double bond in the molecule, and a maleimide compound (A-3). Each of these will be explained in more detail below.

### (Polyphenylene Ether Compound (A-1))

Examples of the polyphenylene ether compound (A-1) having a carbon-carbon unsaturated double bond in the molecule include polyphenylene ether compounds having a group represented by the following Formula (1) or Formula (2). It is considered that a resin composition, which can provide a cured product exhibiting low dielectric properties and high heat resistance, is obtained by containing such a modified polyphenylene ether compound.

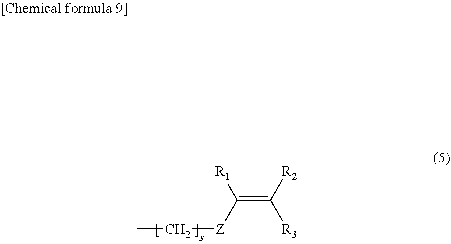

In Formula (5), s represents an integer from 0 to 10. Z represents an arylene group. R₁ to R₃ are independent of each other. In other words, R₁ to R₃ may be the same group as or different groups from each other. R₁ to R₃ represent a hydrogen atom or an alkyl group.

In a case where s in Formula (5) is 0, it indicates that Z is directly bonded to the terminal of polyphenylene ether.

The arylene group of Z is not particularly limited. Examples of this arylene group include a monocyclic aromatic group such as a phenylene group, and a polycyclic aromatic group in which the aromatic is not a single ring but a polycyclic aromatic such as a naphthalene ring. This arylene group also includes a derivative in which a hydrogen atom bonded to an aromatic ring is substituted with a functional group such as an alkenyl group, an alkynyl group, a formyl group, an alkylcarbonyl group, an alkenylcarbonyl group, or an alkynylcarbonyl group. In addition, the alkyl group is not particularly limited and is, for example, preferably an alkyl group having 1 to 18 carbon atoms and more preferably an alkyl group having 1 to 10 carbon atoms. Specific examples thereof include a methyl group, an ethyl group, a propyl group, a hexyl group, and a decyl group.

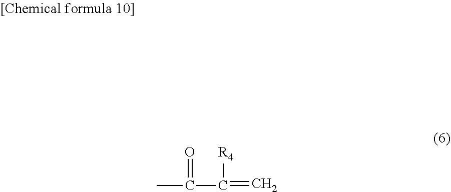

In Formula (6), R₄ represents a hydrogen atom or an alkyl group. The alkyl group is not particularly limited and is, for example, preferably an alkyl group having 1 to 18 carbon atoms and more preferably an alkyl group having 1 to 10 carbon atoms. Specific examples thereof include a methyl group, an ethyl group, a propyl group, a hexyl group, and a decyl group.

Preferred specific examples of the substituent represented by Formula (5) include, for example, a substituent having a vinylbenzyl group. Examples of the substituent having a vinylbenzyl group include a substituent represented by the following Formula (7). Examples of the substituent represented by Formula (6) include an acrylate group and a methacrylate group.

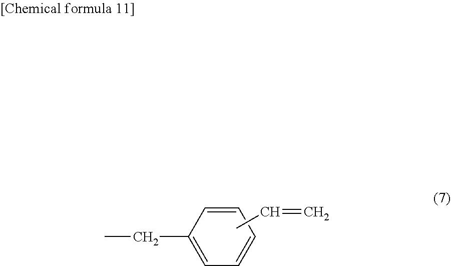

More specific examples of the substituent include vinylbenzyl groups (ethenylbenzyl groups) such as a p-ethenylbenzyl group and an m-ethenylbenzyl group, a vinylphenyl group, an acrylate group, and a methacrylate group.

In the resin composition of the present embodiment, it is more preferable that the polyphenylene ether compound has a group represented by Formula (6). This is because there is thus an advantage that the reactivity with a crosslinking agent is improved and a cured resin product exhibiting high heat resistance is likely to be obtained.

The polyphenylene ether compound has a polyphenylene ether chain in the molecule and preferably has, for example, a repeating unit represented by the following Formula (8) in the molecule.

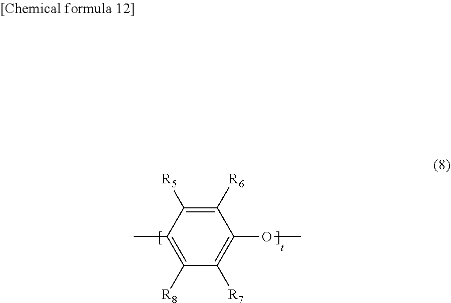

In Formula (8), t represents 1 to 50. R₅ to R₈ are independent of each other. In other words, R₅ to R₈ may be the same group as or different groups from each other. R₅ to R₈ represent a hydrogen atom, an alkyl group, an alkenyl group, an alkynyl group, a formyl group, an alkylcarbonyl group, an alkenylcarbonyl group, or an alkynylcarbonyl group. Among these, a hydrogen atom and an alkyl group are preferable.

Specific examples of the respective functional groups mentioned in R₅ to R₈ include the following.

The alkyl group is not particularly limited and is, for example, preferably an alkyl group having 1 to 18 carbon atoms and more preferably an alkyl group having 1 to 10 carbon atoms. Specific examples thereof include a methyl group, an ethyl group, a propyl group, a hexyl group, and a decyl group.

The alkenyl group is not particularly limited and is, for example, preferably an alkenyl group having 2 to 18 carbon atoms and more preferably an alkenyl group having 2 to 10 carbon atoms. Specific examples thereof include a vinyl group, an allyl group, and a 3-butenyl group.

The alkynyl group is not particularly limited and is, for example, preferably an alkynyl group having 2 to 18 carbon atoms and more preferably an alkynyl group having 2 to 10 carbon atoms. Specific examples thereof include an ethynyl group and a prop-2-yn-1-yl group (propargyl group).

The alkylcarbonyl group is not particularly limited as long as it is a carbonyl group substituted with an alkyl group and is, for example, preferably an alkylcarbonyl group having 2 to 18 carbon atoms and more preferably an alkylcarbonyl group having 2 to 10 carbon atoms. Specific examples thereof include an acetyl group, a propionyl group, a butyryl group, an isobutyryl group, a pivaloyl group, a hexanoyl group, an octanoyl group, and a cyclohexylcarbonyl group.

The alkenylcarbonyl group is not particularly limited as long as it is a carbonyl group substituted with an alkenyl group and is, for example, preferably an alkenylcarbonyl group having 3 to 18 carbon atoms and more preferably an alkenylcarbonyl group having 3 to 10 carbon atoms. Specific examples thereof include an acryloyl group, a methacryloyl group, and a crotonoyl group.

The alkynylcarbonyl group is not particularly limited as long as it is a carbonyl group substituted with an alkynyl group and is, for example, preferably an alkynylcarbonyl group having 3 to 18 carbon atoms and more preferably an alkynylcarbonyl group having 3 to 10 carbon atoms. Specific examples thereof include a propioloyl group.

The weight average molecular weight (Mw) of the polyphenylene ether compound is not particularly limited. Specifically, the weight average molecular weight is preferably 500 to 5000, more preferably 800 to 4000, and still more preferably 1000 to 3000. The weight average molecular weight may be measured by a general molecular weight measurement method, and specific examples thereof include a value measured by gel permeation chromatography (GPC). In a case where the polyphenylene ether compound has a repeating unit represented by Formula (8) in the molecule, t is preferably a numerical value so that the weight average molecular weight of the polyphenylene ether compound is in such a range. Specifically, t is preferably 1 to 50.

When the weight average molecular weight of the polyphenylene ether compound is in such a range, the polyphenylene ether compound exhibits the excellent low dielectric properties of polyphenylene ether and not only imparts superior heat resistance to the cured product but also exhibits excellent moldability. This is considered to be due to the following. When the weight average molecular weight of ordinary polyphenylene ether is in such a range, the heat resistance of the cured product tends to decrease since the molecular weight is relatively low. With regard to this point, since the polyphenylene ether compound according to the present embodiment has one or more unsaturated double bonds at the terminal, it is considered that a cured product exhibiting sufficiently high heat resistance is obtained. When the weight average molecular weight of the polyphenylene ether compound is in such a range, the polyphenylene ether compound has a relatively low molecular weight and is thus considered to exhibit excellent moldability as well. Hence, it is considered that such a polyphenylene ether compound not only imparts superior heat resistance to the cured product but also exhibits excellent moldability.

In the polyphenylene ether compound, the average number of the substituents (number of terminal functional groups) at the molecule terminal per one molecule of the polyphenylene ether compound is not particularly limited. Specifically, the average number is preferably 1 to 5, more preferably 1 to 3, and still more preferably 1.5 to 3. When the number of terminal functional groups is too small, sufficient heat resistance of the cured product tends to be hardly attained. When the number of terminal functional groups is too large, the reactivity is too high and, for example, troubles such as deterioration in the storage stability of the resin composition or deterioration in the fluidity of the resin composition may occur. In other words, when such a polyphenylene ether compound is used, for example, molding defects such as generation of voids at the time of multilayer molding occur by insufficient fluidity and the like and a problem of moldability that a highly reliable printed wiring board is hardly obtained may occur.

The number of terminal functional groups in the polyphenylene ether compound includes a numerical value expressing the average value of the substituents per one molecule of all the modified polyphenylene ether compounds present in 1 mole of the polyphenylene ether compound. This number of terminal functional groups can be determined, for example, by measuring the number of hydroxyl groups remaining in the obtained modified polyphenylene ether compound and calculating the number of hydroxyl groups decreased from the number of hydroxyl groups in the polyphenylene ether before being modified. The number of hydroxyl groups decreased from the number of hydroxyl groups in the polyphenylene ether before being modified is the number of terminal functional groups. With regard to the method for measuring the number of hydroxyl groups remaining in the modified polyphenylene ether compound, the number of hydroxyl groups can be determined by adding a quaternary ammonium salt (tetraethylammonium hydroxide) to be associated with a hydroxyl group to a solution of the modified polyphenylene ether compound and measuring the UV absorbance of the mixed solution.

The intrinsic viscosity of the polyphenylene ether compound of the present embodiment is not particularly limited. Specifically, the intrinsic viscosity may be 0.03 to 0.12 dl/g, and is preferably 0.04 to 0.11 dl/g and more preferably 0.06 to 0.095 dl/g. When the intrinsic viscosity is too low, the molecular weight tends to be low and low dielectric properties such as a low dielectric constant and a low dielectric loss tangent tend to be hardly attained. When the intrinsic viscosity is too high, the viscosity is high, sufficient fluidity is not attained, and the moldability of the cured product tends to decrease. Thus, when the intrinsic viscosity of the polyphenylene ether compound is in the above range, excellent heat resistance and moldability of the cured product can be realized.

Note that the intrinsic viscosity here is an intrinsic viscosity measured in methylene chloride at 25° C. and more specifically is, for example, a value attained by measuring the intrinsic viscosity of a methylene chloride solution (liquid temperature: 25° C.) at 0.18 g/45 ml using a viscometer. Examples of the viscometer include AVS500 Visco System manufactured by SCHOTT Instruments GmbH.

Examples of the polyphenylene ether compound of the present embodiment include a modified polyphenylene ether compound represented by the following Formula (9) and a modified polyphenylene ether compound represented by the following Formula (10). As the polyphenylene ether compound of the present embodiment, these modified polyphenylene ether compounds may be used singly or these two modified polyphenylene ether compounds may be used in combination.

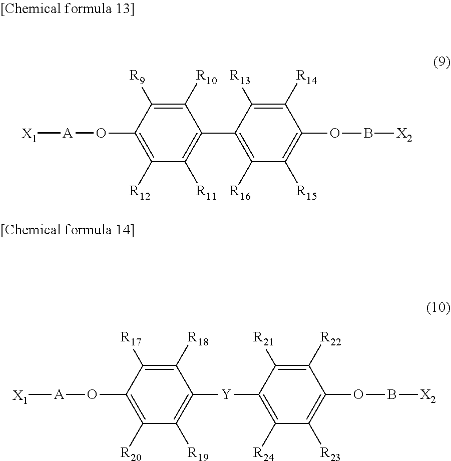

In Formulas (9) and (10), R₉ to R₁₆ and R₁₇ to R₂₄ each independently represent a hydrogen atom, an alkyl group, an alkenyl group, an alkynyl group, a formyl group, an alkylcarbonyl group, an alkenylcarbonyl group, or an alkynylcarbonyl group. X₁ and X₂ each independently represent a substituent having a carbon-carbon unsaturated double bond. A and B represent a repeating unit represented by the following Formula (11) and a repeating unit represented by the following Formula (12), respectively. In Formula (10), Y represents a linear, branched, or cyclic hydrocarbon having 20 or less carbon atoms.

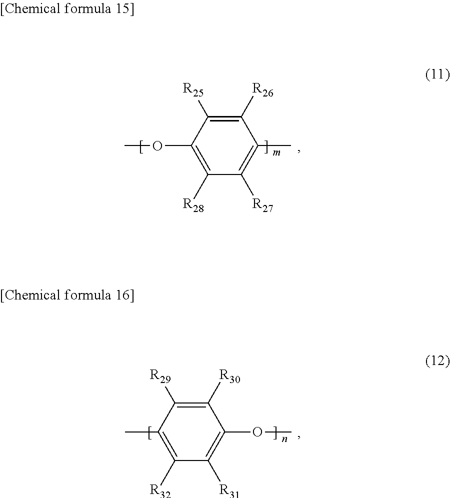

In Formulas (11) and (12), m and n each represent 0 to 20. R₂₅ to R₂₈ and R₂₉ to R₃₂ each independently represent a hydrogen atom, an alkyl group, an alkenyl group, an alkynyl group, a formyl group, an alkylcarbonyl group, an alkenylcarbonyl group, or an alkynylcarbonyl group.

The modified polyphenylene ether compound represented by Formula (9) and the modified polyphenylene ether compound represented by Formula (10) are not particularly limited as long as they are compounds satisfying the above configuration. Specifically, in Formulas (9) and (10), R₉ to R₁₆ and R₁₇ to R₂₄ are independent of each other as described above. In other words, R₉ to R₁₆ and R₁₇ to R₂₄ may be the same group as or different groups from each other. R₉ to R₁₆ and R₁₇ to R₂₄ represent a hydrogen atom, an alkyl group, an alkenyl group, an alkynyl group, a formyl group, an alkylcarbonyl group, an alkenylcarbonyl group, or an alkynylcarbonyl group. Among these, a hydrogen atom and an alkyl group are preferable.

In Formulas (11) and (12), m and n each preferably represent 0 to 20 as described above. In addition, it is preferable that m and n represent numerical values so that the sum of m and n is 1 to 30. Hence, it is more preferable that m represents 0 to 20, n represents 0 to 20, and the sum of m and n represents 1 to 30. R₂₅ to R₂₈ and R₂₉ to R₃₂ are independent of each other. In other words, R₂₅ to R₂₈ and R₂₉ to R₃₂ may be the same group as or different groups from each other. R₂₅ to R₂₈ and R₂₉ to R₃₂ represent a hydrogen atom, an alkyl group, an alkenyl group, an alkynyl group, a formyl group, an alkylcarbonyl group, an alkenylcarbonyl group, or an alkynylcarbonyl group. Among these, a hydrogen atom and an alkyl group are preferable.

R₉ to R₃₂ are the same as R₅ to R₈ in Formula (8).

In Formula (10), Y represents a linear, branched, or cyclic hydrocarbon having 20 or less carbon atoms as described above. Examples of Y include a group represented by the following Formula (13).

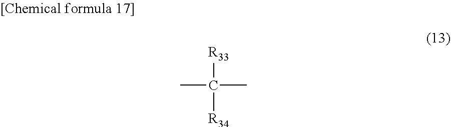

In Formula (13), R₃₃ and R₃₄ each independently represent a hydrogen atom or an alkyl group. Examples of the alkyl group include a methyl group. Examples of the group represented by Formula (13) include a methylene group, a methylmethylene group, and a dimethylmethylene group. Among these, a dimethylmethylene group is preferable.

In Formulas (9) and (10), X₁ and X₂ each independently represent a substituent having a carbon-carbon unsaturated double bond. The substituents X₁ and X₂ are not particularly limited as long as they are substituents having a carbon-carbon unsaturated double bond. Examples of the substituents X₁ and X₂ include a substituent represented by Formula (5) and a substituent represented by Formula (6). In the modified polyphenylene ether compound represented by Formula (9) and the modified polyphenylene ether compound represented by Formula (10), X₁ and X₂ may be the same substituent as or different substituents from each other.

More specific examples of the modified polyphenylene ether compound represented by Formula (9) include a modified polyphenylene ether compound represented by the following Formula (14).

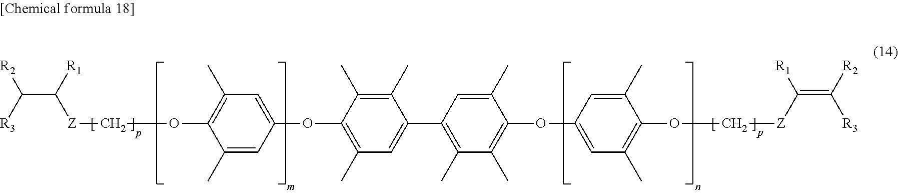

More specific examples of the modified polyphenylene ether compound represented by Formula (10) include a modified polyphenylene ether compound represented by the following Formula (15) and a modified polyphenylene ether compound represented by the following Formula (16).

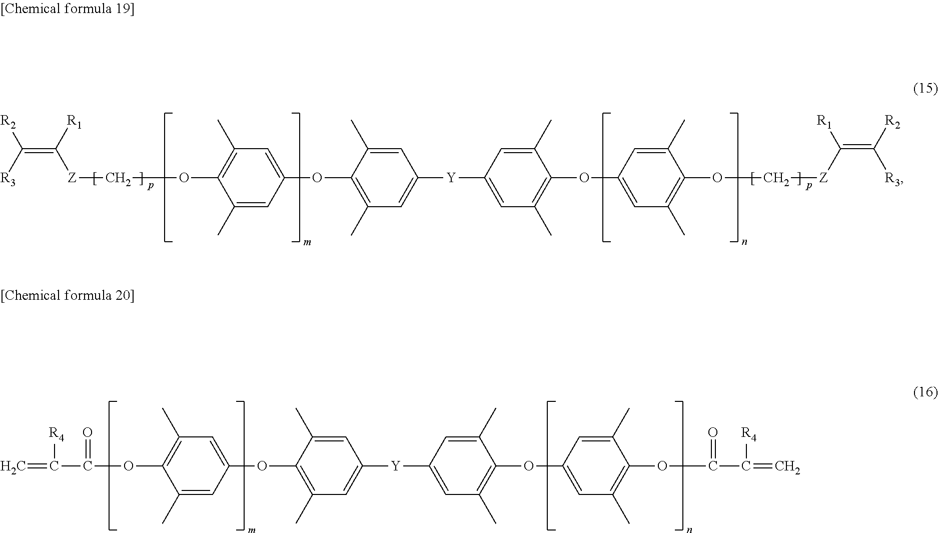

In Formulas (14) to (16), m and n are the same as m and n in Formulas (11) and (12). In Formulas (14) and (15), R₁ to R₃, p, and Z are the same as R₁ to R₃, s, and Z in Formula (5), respectively. In Formulas (15) and (16), Y is the same as Y in the above (10). In Formula (16), R₄ is the same as R₄ in Formula (6).

It is considered that by using a modified polyphenylene ether compound as described above, low dielectric properties such as a low dielectric constant, excellent heat resistance, and the like can be maintained as well as a high Tg and close contact properties can be improved.

One kind of the modified polyphenylene ether compounds can be used singly, or two or more kinds thereof can be used in combination.

The polyphenylene ether compound used in the resin composition of the present embodiment can be synthesized by a known method, or a commercially available polyphenylene ether compound can also be used. Examples of the commercially available product include: “OPE-2st 1200” and “OPE-2st 2200” manufactured by Mitsubishi Gas Chemical Company Inc., and “SA 9000” manufactured by SABIC Innovative Plastics.

### Hydrocarbon-Based Compound (A-2) Having Carbon-Carbon Unsaturated Double Bond in Molecule

The hydrocarbon-based resin that can be used in the present embodiment is not particularly limited as long as it is a hydrocarbon-based resin having an unsaturated double bond, and for example, there can be preferably exemplified hydrocarbon-based resins of a polyfunctional vinyl aromatic polymer, of a cyclic polyolefin resin, or of a vinyl aromatic compound-conjugated diene-based compound copolymer.

The polyfunctional vinyl aromatic polymer is preferably a polymer including a polymerized product of at least a polyfunctional vinyl aromatic compound and/or a derivative thereof, and is not particularly limited as long as it is a polymer including a structure derived from a polyfunctional vinyl aromatic compound and/or a derivative thereof, and may be a polymer including a structure derived from one or more polyfunctional vinyl aromatic compounds and/or derivatives thereof.

In addition to the structural units derived from a polyfunctional vinyl aromatic compound and/or a derivative thereof, one or more structural units derived from reactive monomers may be further contained. The reactive monomer is not particularly limited, but may be, for example, a polyfunctional vinyl aromatic copolymer having a structural unit derived from a monovinyl aromatic compound such as styrene.

More specific examples thereof include a polyfunctional vinyl compound having two or more vinyl groups in the molecule. Examples of the polyfunctional vinyl compound include divinylbenzene, divinylnaphthalene, divinylbiphenyl, and polybutadiene.

### Maleimide Compound (A-3)

As the maleimide resin that can be used in the present embodiment, a compound that includes a maleimide group in the molecule can be used without particular limitation. Specifically, examples of the maleimide compound include: monofunctional maleimide compounds including one maleimide group in the molecule, polyfunctional maleimide compounds including two or more maleimide groups in the molecule, and modified maleimide compounds. Examples of the modified maleimide compound include a modified maleimide compound in which a part of the molecule is modified with an amine compound, a modified maleimide compound in which a part of the molecule is modified with a silicone compound, and a modified maleimide compound in which a part of the molecule is modified with an amine compound and a silicone compound.

More specifically, examples include: maleimide compounds having two or more N-substituted maleimide groups in one molecule, maleimide compounds having an indane structure, maleimide compound having at least one selected from among an alkyl group with 6 or more carbon atoms and an alkylene group with 6 or more carbon atoms, and maleimide compounds having a benzene ring in the molecule.

The maleimide compound used in the present embodiment may be commercially available maleimide compounds, and for example, BMI-4000, BMI-2300, BMI-TMH, BMI-4000, BMI-5100, and the like manufactured by Daiwa Fine Chemicals Co., Ltd.; MIR-3000 and MIR-5000 manufactured by Nippon Kayaku Co., Ltd.; and BMI-689, BMI-1500, BMI-3000J, BMI-5000 and the like manufactured by Designer Molecules Inc. may be used.

### Other Radical Polymerizable Compounds (Curing Agents)

The resin composition of the present embodiment may further contain a radical polymerizable compound other than the radical polymerizable compound as described above. Such a radical polymerizable compound is preferably a radical polymerizable compound that acts as a curing agent capable of reacting with the radical polymerizable compound as described above.

Specific examples thereof include a phenol resin, a benzoxazine compound, a liquid crystal polymer, styrene, a styrene derivative, a compound having an acryloyl group in the molecule, a compound having a methacryloyl group in the molecule, a compound having a vinyl group in the molecule, a compound having an allyl group in the molecule, a compound having an acenaphthylene structure in the molecule, and an isocyanurate compound having an isocyanurate group in the molecule. These can be used singly, or may be used in combination of two or more kinds thereof with the radical polymerizable compound as described above.

Examples of the styrene derivatives include bromostyrene and dibromostyrene.

The compound having an acryloyl group in the molecule is an acrylate compound. Examples of the acrylate compound include a monofunctional acrylate compound having one acryloyl group in the molecule and a polyfunctional acrylate compound having two or more acryloyl groups in the molecule. Examples of the monofunctional acrylate compound include methyl acrylate, ethyl acrylate, propyl acrylate, and butyl acrylate. Examples of the polyfunctional acrylate compound include tricyclodecanedimethanol diacrylate.

The compound having a methacryloyl group in the molecule is a methacrylate compound. Examples of the methacrylate compound include a monofunctional methacrylate compound having one methacryloyl group in the molecule and a polyfunctional methacrylate compound having two or more methacryloyl groups in the molecule. Examples of the monofunctional methacrylate compound include methyl methacrylate, ethyl methacrylate, propyl methacrylate, and butyl methacrylate. Examples of the polyfunctional methacrylate compound include tricyclodecanedimethanol dimethacrylate.

The compound having a vinyl group in the molecule is a vinyl compound. Examples of the vinyl compound include a monofunctional vinyl compound (monovinyl compound) having one vinyl group in the molecule.

The compound having an allyl group in the molecule is an allyl compound. Examples of the allyl compound include a monofunctional allyl compound having one allyl group in the molecule and a polyfunctional allyl compound having two or more allyl groups in the molecule. Examples of the polyfunctional allyl compound include diallyl phthalate (DAP).

The compound having an acenaphthylene structure in the molecule is an acenaphthylene compound. Examples of the acenaphthylene compound include acenaphthylene, alkylacenaphthylenes, halogenated acenaphthylenes, and phenylacenaphthylenes. Examples of the alkyl acenaphthylenes include 1-methyl acenaphthylene, 3-methyl acenaphthylene, 4-methyl acenaphthylene, 5-methyl acenaphthylene, 1-ethyl acenaphthylene, 3-ethyl acenaphthylene, 4-ethyl acenaphthylene, and 5-ethyl acenaphthylene. Examples of the halogenated acenaphthylenes include 1-chloroacenaphthylene, 3-chloroacenaphthylene, 4-chloroacenaphthylene, 5-chloroacenaphthylene, 1-bromoacenaphthylene, 3-bromoacenaphthylene, 4-bromoacenaphthylene, and 5-bromoacenaphthylene. Examples of the phenylacenaphthylenes include 1-phenylacenaphthylene, 3-phenylacenaphthylene, 4-phenylacenaphthylene, and 5-phenylacenaphthylene. The acenaphthylene compound may be a monofunctional acenaphthylene compound having one acenaphthylene structure in the molecule as described above or may be a polyfunctional acenaphthylene compound having two or more acenaphthylene structures in the molecule.

The compound having an isocyanurate group in the molecule is an isocyanurate compound. Examples of the isocyanurate compound include a compound having an alkenyl group in the molecule (alkenyl isocyanurate compound), and examples thereof include a trialkenyl isocyanurate compound such as triallyl isocyanurate (TAIC).

Among the above, for example, a polyfunctional acrylate compound having two or more acryloyl groups in the molecule, a polyfunctional methacrylate compound having two or more methacryloyl groups in the molecule, a polyfunctional vinyl compound having two or more vinyl groups in the molecule, a styrene derivative, an allyl compound having an allyl group in the molecule, a maleimide compound having a maleimide group in the molecule, an acenaphthylene compound having an acenaphthylene structure in the molecule, and an isocyanurate compound having an isocyanurate group in the molecule are preferable.

The radical polymerizable compounds, which are used as a curing agent, as described above all may be used singly or in combination of two or more kinds thereof.

In a case where the resin composition of the present embodiment contains other radical polymerizable compounds (acting as a curing agent) in addition to the radical polymerizable compounds (A-1) to (A-3), the content ratio of the radical polymerizable compounds (A-1) to (A-3) to other radical polymerizable compounds is preferably about 95:5 to 50:50.

### (Inorganic Filler (B))

The resin composition according to the present embodiment contains an inorganic filler (B) containing boron nitride (B-1) and silica (B-2).

The boron nitride (B-1) is not particularly limited as long as it can be used as an inorganic filler contained in a resin composition. Examples of boron nitride include normal pressure phase of hexagonal boron nitride (h-BN) and high pressure phase of cubic boron nitride (c-BN).

The boron nitride of the present embodiment preferably includes at least one or more kinds of boron nitrides having an average particle size of 0.5 to 30 μm. Furthermore, it is preferable to include at least at least one or more kinds of boron nitrides having an average particle size of 2 to 20 μm. When the boron nitride is too small, there is a tendency that the thermal conductivity and heat resistance of a cured product of the obtained resin composition cannot be sufficiently increased. When the boron nitride is too large, the moldability of the obtained resin composition tends to decrease. Hence, when the average particle size of the boron nitride is in the above range, a resin composition that becomes a cured product having a high thermal conductivity and high heat resistance can be obtained more suitably. In this specification, the average particle size refers to the volume average particle size. The volume average particle size can be measured by, for example, a laser diffraction method and the like. As the boron nitride of the present embodiment, two or more kinds of boron nitride fillers having different average particle sizes may be used concurrently among boron nitride fillers included in the above range.

Silica (B-2) used in the resent embodiment is not particularly limited as long as it can be used as an inorganic filler. The silica of the present embodiment may be silica subjected to surface treatment or silica not subjected to surface treatment. Examples of the surface treatment include treatment with a silane coupling agent.

Examples of the silane coupling agent include silane coupling agents having at least one functional group selected from the group consisting of a vinyl group, a styryl group, a methacryloyl group, an acryloyl group, and a phenylamino group. In other words, examples of this silane coupling agent include compounds having at least one of a vinyl group, a styryl group, a methacryloyl group, an acryloyl group, or a phenylamino group as a functional group, and further a hydrolyzable group such as a methoxy group or an ethoxy group.

Examples of the silane coupling agent include vinyltriethoxysilane and vinyltrimethoxysilane as those having a vinyl group. Examples of the silane coupling agent include p-styryltrimethoxysilane and p-styryltriethoxysilane as those having a styryl group. Examples of the silane coupling agent include 3-methacryloxypropyltrimethoxysilane, 3-methacryloxypropylmethyldimethoxysilane, 3-methacryloxypropyltriethoxysilane, 3-methacryloxypropylmethyldiethoxysilane, and 3-methacryloxypropylethyldiethoxysilane as those having a methacryloyl group. Examples of the silane coupling agent include 3-acryloxypropyltrimethoxysilane and 3-acryloxypropyltriethoxysilane as those having an acryloyl group. Examples of the silane coupling agent include N-phenyl-3-aminopropyltrimethoxysilane and N-phenyl-3-aminopropyltriethoxysilane as those having a phenylamino group.

The average particle size of the silica is preferably 0.05 to 10 μm, more preferably 0.5 to 5 μm. When the silica is too small, the moldability of a cured product of the resin composition tends to deteriorate. When the silica is too large, there is a tendency that the heat resistance of a cured product of the obtained resin composition cannot be sufficiently enhanced.

The resin composition of the present embodiment may further contain an inorganic filler other than the boron nitride (B-1) and silica (B-2). The inorganic filler other than the boron nitride and silica are not particularly limited as long as it can be used as an inorganic filler contained in a resin composition. Examples of the inorganic filler other than the boron nitride include metal oxides such as alumina, titanium oxide, magnesium oxide and mica, metal hydroxides such as magnesium hydroxide and aluminum hydroxide, talc, aluminum borate, barium sulfate, aluminum nitride, silicon nitride, magnesium carbonate such as anhydrous magnesium carbonate, and calcium carbonate. As the inorganic filler other than the boron nitride, silica, anhydrous magnesium carbonate, alumina, silicon nitride, and the like are preferable among these. The silica is not particularly limited, and examples thereof include crushed silica and silica particles, and silica particles are preferable. The magnesium carbonate is not particularly limited, but anhydrous magnesium carbonate (synthetic magnesite) is preferable.

The inorganic filler other than the boron nitride and silica may also be an inorganic filler subjected to a surface treatment or an inorganic filler not subjected to a surface treatment. Examples of the surface treatment include treatment with a silane coupling agent.

The content of the inorganic filler (B) in the resin composition of the present embodiment is preferably 200 to 500 mass %, more preferably 200 to 450 mass % with respect to the total solid amount in the resin composition of the present embodiment. The solids in the resin composition mean solids in the resin that remains after volatile components such as the solvent are removed from the resin composition.

When the content of the inorganic filler (B) is in the above range, it is considered that both sufficient thermal conductivity and moldability can be achieved. In other words, it is possible to more reliably provide a resin composition that provides a cured product having a high thermal conductivity and exhibits excellent moldability.

In the inorganic filler (B) of the present embodiment, the content of the boron nitride (B-1) is preferably 10 to 80 parts by mass, more preferably 30 to 70 parts by mass with respect to 100 parts by mass of the sum of boron nitride (B-1) and silica (B-2). There is thus an advantage that a cured resin product having a high thermal conductivity while maintaining a favorable varnish viscosity is obtained.

### (Free Radical Compound (C))

The free radical compound (C) used in the present embodiment is not particularly limited as long as it is a free radical compound having at least one of the structures represented by Formulas (1) to (4). The free radical compound of the present embodiment is a compound different from the above-described radical polymerizable compound (A) in that it slows radical reactions by trapping radicals with free radical groups present in the skeleton.

By containing such a free radical compound, it is considered that the resin composition of the present embodiment can exhibit excellent moldability (moldability to be fillable in a circuit pattern) while exhibiting properties such as low dielectric properties and heat resistance. In particular, it is considered that the resin composition can maintain excellent moldability when the inorganic filler containing boron nitride is highly filled as well.

Preferably, the free radical compound of the present embodiment includes at least one compound selected from the following Formulas (17) to (19).

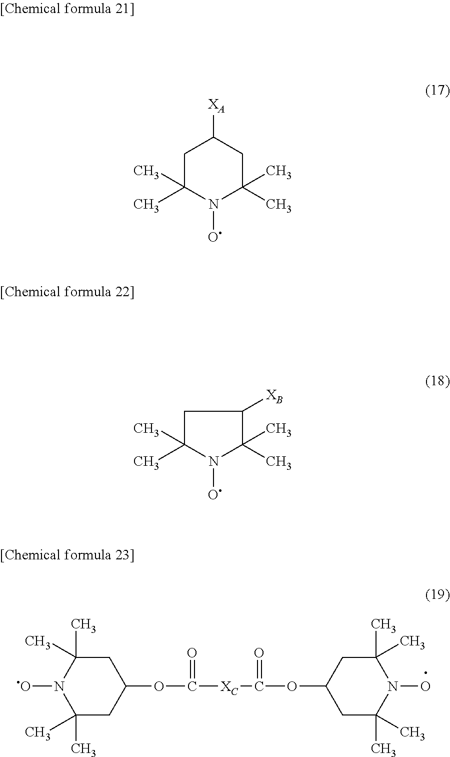

In Formulas (17) and (18), X_{A} and X_{B} each independently represent a hydrogen atom, an amino group, a cyano group, a hydroxy group, an isothiocyanate, a methoxy group, a carboxy group, a carbonyl group, an amide group, a benzoyloxy group, or an ether bond.

More specific examples of these include, for example, 4-acetamide, 4-glycidyloxy, 4-benzoyloxy, 4-(2-iodoacetamide), 4-[2-[2-(4-iodophenoxy) ethoxy]carbonyl]benzoyloxy, 4-methacryloyloxy, 4-oxo, and 4-propargyloxy.

In Formula (19), X_{C} represents an alkylene group, an aromatic structure, a carbonyl group, an amide group, or an ether bond.

The alkylene group may have a linear structure, a side chain structure and/or a cyclic structure, and the lengths of the linear and side chains are not particularly limited. There is a case where the solubility of the resin component in the solvent decreases when the number of carbon atoms becomes too large, and thus, for example, it is preferable that the number of carbon atoms is 16 or less and it is particularly preferable that the number of carbon atoms is about 8 or less.

When the alkylene group has a cyclic structure, examples of the cyclic structure include a seven-membered ring structure, a six-membered ring structure, and a five-membered ring structure.

Examples of the aromatic structure include a phenyl group, a pyrrole group, and a thiazole group.

More specific examples of the free radical compound that is preferably used in the present embodiment include 4-amino-2,2,6,6-tetramethylpiperidin 1-oxyl free radical, 4-acetamide-2,2,6,6-tetramethylpiperidin 1-oxyl free radical, 4-amino-2,2,6,6-tetramethylpiperidin 1-oxyl free radical, 4-carboxy-2,2,6,6-tetramethylpiperidin 1-oxyl free radical, 4-cyano-2,2,6,6-tetramethylpiperidin 1-oxyl free radical, 4-glysidyloxy-2,2,6,6-tetramethylpiperidine 1-oxyl-free radical, 4-hydroxy-2,2,6,6-tetramethylpiperidin 1-oxyl-free radical, 4-hydroxy-2,2,6,6-tetramethylpiperidin 1-oxylbenzoart free radical, 4-isothiocyanato-2,2,6,6-tetramethylpiperidin 1-oxyl free radical, 4-(2-iodoacetamide)-2,2,6,6-tetramethylpiperidin 1-oxyl free radical, 4-[2-[2-(4-iodophenoxy)ethoxy]carbonyl]benzoyloxy-2,2,6,6-tetramethylpiperidine-1-oxyl, 4-methoxy-2,2,6,6-tetramethylpiperidine 1-oxyl free radical, 4-methacryloyloxy-2,2,6,6-tetramethylpiperidine 1-oxyl free radical, 4-oxo-2,2,6,6-tetramethylpiperidin 1-oxyl free radical, 4-oxo-2,2,6,6-tetramethylpiperidine 1-oxyl free radical, 2,2,6,6-tetramethylpiperidine 1-oxyl free radical, 2,2,6,6-tetramethyl-4-(2-propinyloxy)piperidine 1-oxyl free radical, 2,2,6,6-tetramethylpiperidin 1-oxyl free radical, 4,5-dihydro-4,4,5,5-tetramethyl-2-phenyl-1H-imidazole-1-yloxy-1-oxide, bis(2,2,6,6-tetramethyl-4-piperidyl-1-oxyl) sebacate, 3-carboxy-2,2,5,5-tetramethylpyrrolidine 1-oxyl free radical, 4-(2-chloroacetamide)-2,2,6,6-tetramethylpiperidin 1-oxyl free radical, 2-(4-nitrophenyl)-4,4,5,5-tetramethylimidazolin-3-oxide-1-oxyl free radical, 2-(14-carboxytetradecyl)-2-ethyl-4,4-dimethyl-3-oxazolidinyloxy free radical, and 1,1-diphenyl-2-picrylhydrazyl free radical.

Various free radical compounds have been mentioned above, and these may be used singly or in combination of two or more kinds thereof.

As the free radical compounds as described above of the present embodiment, commercially available ones can also be used, and are available from, for example, Tokyo Chemical Industry Co., Ltd.

The content of the free radical compound in the resin composition of the present embodiment is preferably 0.01 to 0.5 parts by mass, more preferably 0.01 to 0.1 parts by mass with respect to 100 parts by mass of the radical polymerizable compound (A).

### (Reaction Initiator (D))

The resin composition of the present embodiment may further contain a reaction initiator (D). The radical polymerization (curing) reaction of the resin composition can proceed even without a reaction initiator. However, a reaction initiator may be added since there is a case where it is difficult to raise the temperature until curing proceeds depending on the process conditions.

The reaction initiator is not particularly limited as long as it can promote the curing reaction of the resin composition. Specific examples thereof include metal oxides, azo compounds, and peroxides, and at least one of peroxides or azo compounds is preferably contained.

Specific examples of the metal oxide include metal salts of carboxylic acids.

Examples of the organic peroxide include α,α′-di(t-butylperoxy)diisopropylbenzene, 2,5-dimethyl-2,5-di(t-butylperoxy)-3-hexyne, benzoyl peroxide, 3,3′,5,5′-tetramethyl-1,4-diphenoquinone, chloranil, 2,4,6-tri-t-butylphenoxyl, t-butylperoxyisopropyl monocarbonate, and azobisisobutyronitrile.

Specific examples of azo compounds include 2,2′-azobis(2,4,4-trimethylpentane), 2,2′-azobis(N-butyl-2-methylpropionamide), and 2,2′-azobis(2-methylbutyronitrile).

Among these, preferred reaction initiators are 2,2′-azobis(2,4,4-trimethylpentane), 2,2′-azobis(N-butyl-2-methylpropionamide) and the like. These reaction initiators slightly affect the dielectric properties. These reaction initiators have a relatively high reaction initiation temperature and thus have an advantage of being able to suppress the promotion of the curing reaction at the time point at which curing is not required, for example, at the time of prepreg drying, and the decrease in storage stability of the resin composition.

The reaction initiators as described above may be used singly or in combination of two or more kinds thereof.

In a case where the resin composition of the present embodiment contains the reaction initiator (D), the content thereof is not particularly limited, but is, for example, preferably 0.1 to 5.0 parts by mass, more preferably 0.5 to 3.0 parts by mass, still more preferably 0.5 to 2.0 parts by mass with respect to 100 parts by mass of the sum of the radical polymerizable compound (A)

In a case where the resin composition of the present embodiment contains the reaction initiator (D), the content of the free radical compound (C) is 0.5 to 10 parts by mass with respect to 100 parts by mass of the sum of the free radical compound (C) and the reaction initiator (D).

### (Other Elastomers)

In addition to the above-described radical polymerizable compound (A), a thermoplastic resin not having an unsaturated group may be added to the resin composition of the present embodiment in order to more reliably secure low dielectric properties, adhesive strength, and the like.

Examples of the thermoplastic resin include: thermoplastic polyphenylene ether resins, polyphenylene sulfide resins, liquid crystal polymers, polyethylene resins, polystyrene resins, polyurethane resins, polypropylene resins, ABS resins, acrylic resins, polyethylene terephthalate resins, polycarbonate resins, polyacetal resins, polyimide resins, polyamideimide resins, polytetrafluoroethylene resins, cycloolefin polymers, cycloolefin copolymers, and styrenic elastomers. The resins may be used singly, or two or more thereof may be used concurrently.

Among them, the styrenic elastomer is a polymer obtained by polymerizing a monomer containing a styrenic monomer, and may be a styrenic copolymer. Examples of the styrenic copolymer include: copolymers obtained by copolymerizing one or more styrenic monomers and one or more of other monomers copolymerizable with the styrenic monomers. The styrenic copolymer may be a random copolymer or a block copolymer as long as a structure derived from the styrenic monomer is included in the molecule. Examples of the block copolymer include a bipolymer of the structure (repeating unit) derived from the styrenic monomer and the other copolymerizable monomer (repeating unit) and a terpolymer of the structure (repeating unit) derived from the styrenic monomer, the other copolymerizable monomer (repeating unit), and the structure (repeating unit) derived from the styrenic monomer.

The styrenic elastomer may be a hydrogenated styrenic copolymer obtained by hydrogenating the styrenic copolymer.

As the styrenic elastomer, one styrenic polymer may be used singly, or two or more thereof may be used in combination.

As the styrenic elastomer, there may be used an acid anhydride-modified styrenic elastomer obtained by modifying a moiety of the molecule with an acid anhydride.

The styrenic elastomer preferably has a weight average molecular weight of 1000 to 300000, more preferably 1200 to 200000. When the molecular weight is too low, a cured product of the resin composition tends to have a decreased glass transition temperature or to be deteriorated in heat resistance. When the molecular weight is too high, the viscosity of the resin composition when prepared in the form of a varnish and the viscosity of the resin composition during heat molding tend to be too high. The weight average molecular weight is only required to be one measured by a general molecular weight measurement method, and specific examples thereof include a value measured by gel permeation chromatography (GPC).

As the styrenic elastomer, commercially available products can be used, and for example, SEPTON (registered trademark) and HYBRAR (registered trademark) manufactured by Kuraray Co., Ltd., MILASTOMER (registered trademark) manufactured by Mitsui Chemicals Inc., Tuftec (registered trademark) and Tuftrene (registered trademark) manufactured by Asahi Kasei Corporation, DYNARON (registered trademark) manufactured by JSR Corporation, and SIBSTAR (registered trademark) manufactured by Kaneka Corporation may be used.

In a case where the resin composition of the present embodiment contains a thermoplastic resin not having an unsaturated group, the content thereof is preferably about 0.1 to 30 parts by mass, more preferably about 1 to 15 parts by mass with respect to 100 parts by mass of the sum of the component (A) and the thermoplastic resin.

### (Other Components)

The resin composition according to the present embodiment may contain components (other components) in addition to the components described above if necessary as long as the effects of the present invention are not impaired. As other components contained in the resin composition according to the present embodiment, for example, additives such as a flame retardant, a silane coupling agent, an antifoaming agent, an antioxidant, a heat stabilizer, an antistatic agent, an ultraviolet absorber, a dye or a pigment, a dispersant, and a lubricant may be further contained.

The flame retardant is not particularly limited, but examples thereof include halogen-containing flame retardants such as polybrominated biphenyl, polybrominated diphenyl ether, hexabromocyclododecane, tetrabromobisphenol A, and 2,4,6-tribromophenol; phosphoric acid ester compounds, phosphazene compounds, phosphoric acid ester amide compounds, HCA derivatives, red phosphorus, and dialkylphosphinic acid salts. The content of the flame retardant is preferably about 5 to 100 parts by mass, more preferably about 5 to 50 parts by mass with respect to 100 parts by mass of the component (A).

### (Production Method)

The method for producing the resin composition is not particularly limited, and examples thereof include a method in which the radical polymerizable compound (A) is mixed with other components if necessary, and then an inorganic filler is added. Specific examples thereof include the method to be described in the description of prepreg later in the case of obtaining a varnish-like composition containing an organic solvent.

Moreover, by using the resin composition according to the present embodiment, a prepreg, a metal-clad laminate, a wiring board, a metal foil with resin, and a film with resin can be obtained as described below.

It is preferable that a cured product of the resin composition has a thermal conductivity of 1.0 W/m·K or more and a relative dielectric constant of 4.0 or less at a frequency of 10 GHz. In this way, by using the resin composition of the present embodiment, the cured product thereof can have both a high thermal conductivity and low dielectric properties. The resin composition of the present embodiment can secure a sufficient varnish viscosity for molding, and also exhibits excellent moldability.

### [Prepreg]

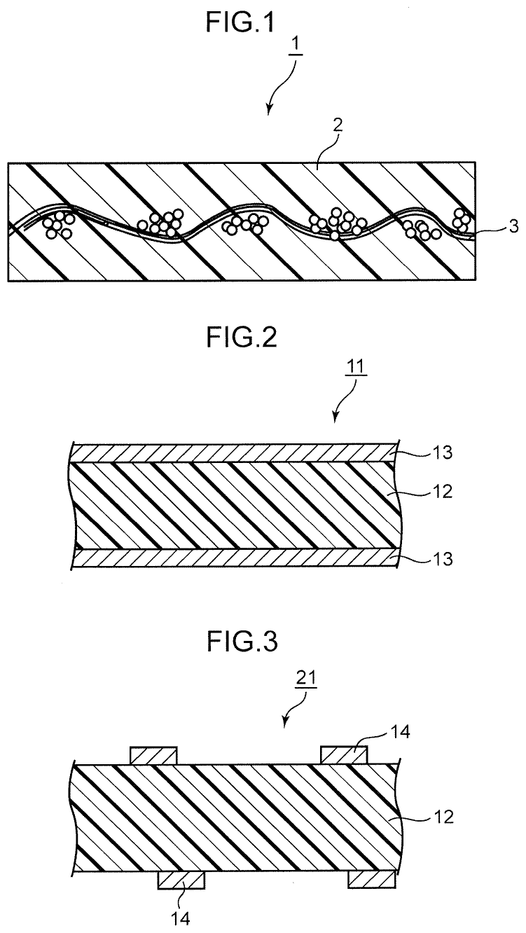

FIG. 1 is a schematic sectional view illustrating an example of a prepreg 1 according to an embodiment of the present invention. In the following description, the reference numerals in the drawings denote: 1 prepreg, 2 resin composition or semi-cured product of resin composition, 3 fibrous base material, 11 metal-clad laminate, 12 insulating layer, 13 metal foil, 14 wiring, 21 wiring board, 31 metal foil with resin, 32 and 42 resin layer, 41 film with resin, and 43 support film, respectively.

As illustrated in FIG. 1, the prepreg 1 according to the present embodiment includes the resin composition or a semi-cured product 2 of the resin composition and a fibrous base material 3. This prepreg 1 includes the resin composition or the semi-cured product 2 of the resin composition and the fibrous base material 3 present in the resin composition or the semi-cured product 2 of the resin composition.

In the present embodiment, the semi-cured product is in a state in which the resin composition has been cured to an extent that the resin composition can be further cured. In other words, the semi-cured product is in a state in which the resin composition has been semi-cured (B-staged). For example, when the resin composition is heated, the viscosity gradually decreases at first, and then curing starts, and then curing starts, and the viscosity gradually increases. In such a case, the semi-cured state includes a state in which the viscosity has started to increase but curing is not completed, and the like.

The prepreg to be obtained using the resin composition according to the present embodiment may include a semi-cured product of the resin composition as described above or include the uncured resin composition itself. In other words, the prepreg may be a prepreg including a semi-cured product of the resin composition (the B-stage resin composition) and a fibrous base material or a prepreg including the resin composition before being cured (the A-stage resin composition) and a fibrous base material. The resin composition or a semi-cured product of the resin composition may be one obtained by drying or heating and drying the resin composition.

When a prepreg is manufactured, the resin composition 2 is often prepared in a varnish form and used in order to be impregnated into the fibrous base material 3 which is a base material for forming the prepreg. In other words, the resin composition 2 is usually a resin varnish prepared in a varnish form in many cases. Such a varnish-like resin composition (resin varnish) is prepared, for example, as follows.

First, the respective components, which can be dissolved in an organic solvent, in the composition of the resin composition are introduced into and dissolved in an organic solvent. At this time, heating may be performed if necessary. Thereafter, components (for example, inorganic filler), which are used if necessary but are not dissolved in the organic solvent, are added to and dispersed in the solution until a predetermined dispersion state is achieved using a ball mill, a bead mill, a planetary mixer, a roll mill or the like, whereby a varnish-like resin composition is prepared. The organic solvent used here is not particularly limited as long as it dissolves the radical polymerizable compound and the like, and does not inhibit the curing reaction. Specific examples thereof include toluene and methyl ethyl ketone (MEK).

The method for manufacturing the prepreg is not particularly limited as long as the prepreg can be manufactured. Specifically, when manufacturing a prepreg, the resin composition which has been described above and is used in the present embodiment is often prepared in a varnish form and used as a resin varnish as described above.

Specific examples of the fibrous base material include glass cloth, aramid cloth, polyester cloth, a glass nonwoven fabric, an aramid nonwoven fabric, a polyester nonwoven fabric, pulp paper, and linter paper. When glass cloth is used, a laminate exhibiting excellent mechanical strength is obtained, and glass cloth subjected to flattening is particularly preferable. Specific examples of the flattening include a method in which glass cloth is continuously pressed at an appropriate pressure using a press roll to flatly compress the yarn. The thickness of the generally used fibrous base material is, for example, 0.01 mm or more and 0.3 mm or less.

The method for manufacturing the prepreg is not particularly limited as long as the prepreg can be manufactured. Specifically, when manufacturing a prepreg, the resin composition according to the present embodiment described above is often prepared in a varnish form and used as a resin varnish as described above.

Examples of the method for manufacturing the prepreg 1 include a method in which the fibrous base material 3 is impregnated with the resin composition 2, for example, the resin composition 2 prepared in a varnish form, and then dried. The fibrous base material 3 is impregnated with the resin composition 2 by dipping, coating, and the like. If necessary, the impregnation can be repeated a plurality of times. Moreover, at this time, it is also possible to finally adjust the composition and impregnated amount to the desired composition and impregnated amount by repeating impregnation using a plurality of resin compositions having different compositions and concentrations.

The fibrous base material 3 impregnated with the resin composition (resin varnish) 2 is heated under desired heating conditions, for example, at 80° C. or more and 180° C. or less for 1 minute or more and 10 minutes or less. By heating, the prepreg 1 before being cured (A-stage) or in a semi-cured state (B-stage) is obtained. By the heating, the organic solvent can be decreased or removed by being volatilized from the resin varnish.

The prepreg including the resin composition according to the present embodiment or a semi-cured product of this resin composition is a prepreg that suitably provides a cured product exhibiting low dielectric properties and a high thermal conductivity. The prepreg of the present embodiment also exhibits favorable moldability.

### [Metal-Clad Laminate]

FIG. 2 is a schematic sectional view illustrating an example of a metal-clad laminate 11 according to an embodiment of the present invention.

As illustrated in FIG. 2, the metal-clad laminate 11 includes an insulating layer 12 containing a cured product of the prepreg 1 illustrated in FIG. 1 and a metal foil 13 to be laminated together with the insulating layer 12. In other words, the metal-clad laminate 11 includes the insulating layer 12 containing a cured product of a resin composition and the metal foil 13 provided on the insulating layer 12. The insulating layer 12 may be formed of a cured product of the resin composition or a cured product of the prepreg. In addition, the thickness of the metal foil 13 varies depending on the performance and the like to be required for the finally obtained wiring board and is not particularly limited. The thickness of the metal foil 13 can be appropriately set depending on the desired purpose and is preferably, for example, 0.2 to 70 μm. Examples of the metal foil 13 include a copper foil and an aluminum foil, and the metal foil 13 may be a copper foil with carrier which includes a release layer and a carrier for the improvement in handleability in a case where the metal foil is thin.

The method for manufacturing the metal-clad laminate 11 is not particularly limited as long as the metal-clad laminate 11 can be manufactured. Specific examples thereof include a method in which the metal-clad laminate 11 is fabricated using the prepreg 1. Examples of this method include a method in which the double-sided metal foil-clad or single-sided metal foil-clad laminate 11 is fabricated by stacking one sheet or a plurality of sheets of prepreg 1, further stacking the metal foil 13 such as a copper foil on both or one of upper and lower surfaces of the prepregs 1, and laminating and integrating the metal foils 13 and prepregs 1 by heating and pressing. In other words, the metal-clad laminate 11 is obtained by laminating the metal foil 13 on the prepreg 1 and then performing heating and pressing. Moreover, the heating and pressing conditions can be appropriately set depending on the thickness of the metal-clad laminate 11 to be manufactured, the kind of the composition of the prepreg 1, and the like. For example, it is possible to set the temperature to 170° C. to 230° C., the pressure to 3 to 5 MPa, and the time to 60 to 150 minutes. Moreover, the metal-clad laminate may be manufactured without using a prepreg. Examples thereof include a method in which a varnish-like resin composition is applied on a metal foil to form a layer containing the resin composition on the metal foil and then heating and pressing is performed.

The metal-clad laminate including an insulating layer containing a cured product of the resin composition according to the present embodiment is a metal-clad laminate that includes an insulating layer exhibiting low dielectric properties and a high thermal conductivity. The moldability is also favorable.

### [Wiring Board]

FIG. 3 is a schematic sectional view illustrating an example of a wiring board 21 according to an embodiment of the present invention.

The wiring board 21 according to the present embodiment is formed of an insulating layer 12 obtained by curing the prepreg 1 illustrated in FIG. 1 and wiring 14 which is laminated together with the insulating layer 12 and is formed by partially removing the metal foil 13 as illustrated in FIG. 3. In other words, the wiring board 21 includes the insulating layer 12 containing a cured product of a resin composition and the wiring 14 provided on the insulating layer 12. The insulating layer 12 may be formed of a cured product of the resin composition or a cured product of the prepreg.

The method for manufacturing the wiring board 21 is not particularly limited as long as the wiring board 21 can be manufactured. Specific examples thereof include a method in which the wiring board 21 is fabricated using the prepreg 1. Examples of this method include a method in which the wiring board 21, in which wiring is provided as a circuit on the surface of the insulating layer 12, is fabricated by forming wiring through etching and the like of the metal foil 13 on the surface of the metal-clad laminate 11 fabricated in the manner described above. In other words, the wiring board 21 is obtained by partially removing the metal foil 13 on the surface of the metal-clad laminate 11 and thus forming a circuit. Examples of the method for forming a circuit include circuit formation by a semi-additive process (SAP) or a modified semi-additive process (MSAP) in addition to the method described above. The wiring board 21 includes the insulating layer 12 which exhibits low dielectric properties and high heat resistance and can suitably maintain the low dielectric properties even after a water absorption treatment.

Such a wiring board is a wiring board that includes an insulating layer exhibiting low dielectric properties and a high thermal conductivity.

[Metal Foil with Resin]

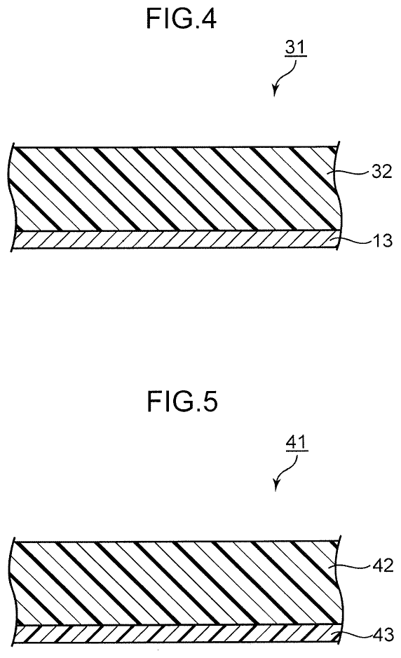

FIG. 4 is a schematic sectional view illustrating an example of a metal foil with resin 31 according to the present embodiment.

The metal foil with resin 31 according to the present embodiment includes a resin layer 32 containing the resin composition or a semi-cured product of the resin composition and a metal foil 13 as illustrated in FIG. 4. The metal foil with resin 31 includes the metal foil 13 on the surface of the resin layer 32. In other words, the metal foil with resin 31 includes the resin layer 32 and the metal foil 13 to be laminated together with the resin layer 32. The metal foil with resin 31 may include other layers between the resin layer 32 and the metal foil 13.

The resin layer 32 may contain a semi-cured product of the resin composition as described above or may contain the uncured resin composition. In other words, the metal foil with resin 31 may be a metal foil with resin including a resin layer containing a semi-cured product of the resin composition (the B-stage resin composition) and a metal foil or a metal foil with resin including a resin layer containing the resin composition before being cured (the A-stage resin composition) and a metal foil. The resin layer is only required to contain the resin composition or a semi-cured product of the resin composition and may or may not contain a fibrous base material. The resin composition or a semi-cured product of the resin composition may be one obtained by drying or heating and drying the resin composition. As the fibrous base material, those similar to the fibrous base materials of the prepreg can be used.

As the metal foil, metal foils to be used in metal-clad laminates can be used without being limited. Examples of the metal foil include a copper foil and an aluminum foil.

The metal foil with resin 31 and a film with resin 41 may include a cover fill and the like if necessary. By including a cover film, it is possible to prevent entry of foreign matter and the like. The cover film is not particularly limited, and examples thereof include a polyolefin film, a polyester film, a polymethylpentene film, and films formed by providing a release agent layer on these films.

The method for manufacturing the metal foil with resin 31 is not particularly limited as long as the metal foil with resin 31 can be manufactured. Examples of the method for manufacturing the metal foil with resin 31 include a method in which the varnish-like resin composition (resin varnish) is applied on the metal foil 13 and heated to manufacture the metal foil with resin 31. The varnish-like resin composition is applied on the metal foil 13 using, for example, a bar coater. The applied resin composition is heated under the conditions of, for example, 80° C. or more and 180° C. or less and 1 minute or more and 10 minutes or less. The heated resin composition is formed as the uncured resin layer 32 on the metal foil 13. By the heating, the organic solvent can be decreased or removed by being volatilized from the resin varnish.

The metal foil with resin including a resin layer containing the resin composition according to the present embodiment or a semi-cured product of this resin composition is a metal foil with resin that suitably provides a cured product exhibiting low dielectric properties and a high thermal conductivity. The moldability is also favorable.

[Film with Resin]

FIG. 5 is a schematic sectional view illustrating an example of a film with resin 41 according to the present embodiment.

The film with resin 41 according to the present embodiment includes a resin layer 42 containing the resin composition or a semi-cured product of the resin composition and a support film 43 as illustrated in FIG. 5. The film with resin 41 includes the resin layer 42 and the support film 43 to be laminated together with the resin layer 42. The film with resin 41 may include other layers between the resin layer 42 and the support film 43.

The resin layer 42 may contain a semi-cured product of the resin composition as described above or may contain the uncured resin composition. In other words, the film with resin 41 may be a film with resin including a resin layer containing a semi-cured product of the resin composition (the B-stage resin composition) and a support film or a film with resin including a resin layer containing the resin composition before being cured (the A-stage resin composition) and a support film. The resin layer is only required to contain the resin composition or a semi-cured product of the resin composition and may or may not contain a fibrous base material. The resin composition or a semi-cured product of the resin composition may be one obtained by drying or heating and drying the resin composition. As the fibrous base material, those similar to the fibrous base materials of the prepreg can be used.

As the support film 43, support films to be used in films with resin can be used without being limited. Examples of the support film include electrically insulating films such as a polyester film, a polyethylene terephthalate (PET) film, a polyimide film, a polyparabanic acid film, a polyether ether ketone film, a polyphenylene sulfide film, a polyamide film, a polycarbonate film, and a polyarylate film.

The film with resin 41 may include a cover film and the like if necessary. By including a cover film, it is possible to prevent entry of foreign matter and the like. The cover film is not particularly limited, and examples thereof include a polyolefin film, a polyester film, and a polymethylpentene film.

The support film and the cover film may be those subjected to surface treatments such as a matt treatment, a corona treatment, a release treatment, and a roughening treatment if necessary.

The method for manufacturing the film with resin 41 is not particularly limited as long as the film with resin 41 can be manufactured. Examples of the method for manufacturing the film with resin 41 include a method in which the varnish-like resin composition (resin varnish) is applied on the support film 43 and heated to manufacture the film with resin 41. The varnish-like resin composition is applied on the support film 43 using, for example, a bar coater. The applied resin composition is heated under the conditions of, for example, 80° C. or more and 180° C. or less and 1 minute or more and 10 minutes or less. The heated resin composition is formed as the uncured resin layer 42 on the support film 43. By the heating, the organic solvent can be decreased or removed by being volatilized from the resin varnish.

The film with resin including a resin layer containing the resin composition according to the present embodiment or a semi-cured product of this resin composition is a film with resin that suitably provides a cured product exhibiting low dielectric properties and a high thermal conductivity. The moldability is also favorable.

This specification discloses techniques in various aspects as described above, and the main techniques among them are summarized below.

The resin composition according to a first aspect of the present invention contains a radical polymerizable compound (A), an inorganic filler (B) containing boron nitride (B-1) and silica (B-2), and a free radical compound (C) having at least one free radical group selected from the group consisting of structures represented by Formulas (1), (2), (3) and (4) in the molecule.

The resin composition according to a second aspect is the resin composition according to the first aspect in which the total content of boron nitride (B-1) and silica (B-2) in the resin composition is 200 to 500 mass % with respect to the total solid amount in the resin composition.

The resin composition according to a third aspect is the resin composition according to the first or second aspect in which the content of the boron nitride (B-1) is 10 to 80 parts by mass with respect to 100 parts by mass of the sum of boron nitride (B-1) and silica (B-2).

The resin composition according to a fourth aspect is the resin composition according to any one of the first to third aspects in which the free radical compound (C) includes at least one compound selected from Formulas (17) to (19).

The resin composition according to a fifth aspect is the resin composition according to any one of the first to fourth aspects in which the radical polymerizable compound (A) includes at least one selected from the group consisting of a polyphenylene ether compound (A-1) having a carbon-carbon unsaturated double bond in the molecule, a hydrocarbon-based compound (A-2) having a carbon-carbon unsaturated double bond in the molecule, and a maleimide compound (A-3).

The resin composition according to a sixth aspect is the resin composition according to any one of the first to fifth aspects, which further contains a reaction initiator (D).

The resin composition according to a seventh aspect is the resin composition according to any one of the first to sixth aspects in which the content of the free radical compound (C) is 0.01 to 0.1 parts by mass with respect to 100 parts by mass of the radical polymerizable compound (A).

The resin composition according to an eighth aspect is the resin composition according to any one of the sixth or seventh aspect in which the content of the free radical compound (C) is 0.5 to 10 parts by mass with respect to 100 parts by mass of the sum of the free radical compound (C) and the reaction initiator (D).

The resin composition according to a ninth aspect is the resin composition according to any one of the first to eighth aspects in which the boron nitride (B-1) includes at least one or more kinds of boron nitrides having an average particle size of 0.5 to 30 μm.

The resin composition according to a tenth aspect is the resin composition according to any one of the first to ninth aspects, which further contains a flame retardant.

The resin composition according to an eleventh aspect is the resin composition according to any one of the first to tenth aspects in which a cured product of the resin composition has a thermal conductivity of 1.0 W/m. K or more and a relative dielectric constant of 4.0 or less at a frequency of 10 GHz.

The prepreg according to a twelfth aspect of the present invention includes the resin composition according to any one of the first to eleventh aspects or a semi-cured product of the resin composition; and a fibrous base material.

The film with resin according to a thirteenth aspect of the present invention includes a resin layer containing the resin composition according to any one of the first to eleventh aspects or a semi-cured product of the resin composition; and a support film.

The metal foil with resin according to a fourteenth aspect of the present invention includes a resin layer containing the resin composition according to any one of the first to eleventh aspects or a semi-cured product of the resin composition; and a metal foil.

The metal-clad laminate according to a fifteenth aspect of the present invention includes an insulating layer containing a cured product of the resin composition according to any one of the first to eleventh aspects or a cured product of the prepreg according to the twelfth aspect; and a metal foil.

The wiring board according to a sixteenth aspect of the present invention includes an insulating layer containing a cured product of the resin composition according to any one of the first to eleventh aspects or a cured product of the prepreg according to the twelfth aspect; and a wiring.

Hereinafter, the present invention will be described more specifically with reference to examples, but the scope of the present invention is not limited thereto.

### EXAMPLES

### Examples 1 to 31 and Comparative Examples 1 to 4

The respective components to be used when preparing a resin composition in the present examples will be described.

### <Radical Polymerizable Compound (A)>

### (A-1)

PPE1: Polyphenylene ether compound having methacryloyl group at terminal (“SA 9000” manufactured by SABIC Innovative Plastics, weight average molecular weight Mw: 2000, number of terminal functional groups: 2)
PPE2: Polyphenylene ether compound having vinylbenzyl group (ethenylbenzyl group) at terminal (OPE-2st 1200 manufactured by Mitsubishi Gas Chemical Company, Inc., Mn 1200)

### (A-2)

DVB: Divinylbenzene (manufactured by NIPPON STEEL CORPORATION)

### (A-3)

Bismaleimide: Bismaleimide resin (MIR-3000 manufactured by Nippon Kayaku Co., Ltd.)

### (Radical Polymerizable Compound Acting as Curing Agent)

TAIC: Triallyl isocyanurate (TAIC manufactured by Nihon Kasei Co., Ltd.)

### <Inorganic Filler (B)>

### (B-1)

Boron nitride 1: “SGP” manufactured by Denka Company Limited, volume average particle size: 18 μm
Boron nitride 2: “HGP” manufactured by Denka Company Limited, volume average particle size: 5 μm
Boron nitride 3: “GP” manufactured by Denka Company Limited, volume average particle size: 7 μm
Boron nitride 4: “AP-10S” manufactured by MARUKA CORPORATION., LTD., volume average particle size: 3.0 μm
Boron nitride 2: “AP-20S” manufactured by MARUKA CORPORATION., LTD., volume average particle size: 2.0 μm

### (B-2)

Silica: “FB-7SDC” manufactured by Denka Company Limited, volume average particle size: 5 μm

### (Others)

Alumina: “DAW-03AC” manufactured by Denka Company Limited, volume average particle size: 8 μm
Synthetic magnesite: Anhydrous magnesium carbonate particles (MAGTHERMO MS-L manufactured by Konoshima Chemical Co., Ltd., volume average particle size: 8 μm)

### <Free Radical Compound (C)>

Free radical compound 1:4-Benzoyloxy-tempo, free radical compound represented by following formula (“H0878” manufactured by Tokyo Chemical Industry Co., Ltd.)

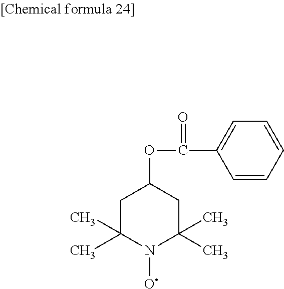

Free radical compound 2: Bis-tempo sebacate, free radical compound represented by following formula (“B5642” manufactured by Tokyo Chemical Industry Co., Ltd.)

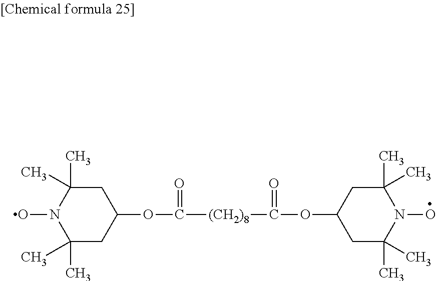

Free radical compound 3: Tempo, free radical compound represented by following formula (“T3751” manufactured by Tokyo Chemical Industry Co., Ltd.)

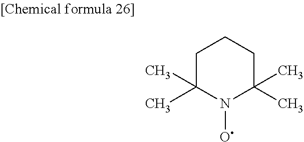

Free radical compound 4: 4H-tempo, free radical compound represented by following formula (“H0865” manufactured by Tokyo Chemical Industry Co., Ltd.)

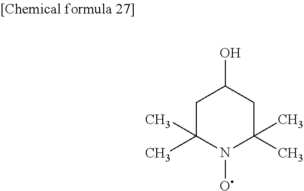

### <Reaction Initiator (D)>

Organic peroxide: PBP (1,3-bis(butylperoxyisopropyl)benzene; PERBUTYL P manufactured by NOF Corporation)
Azo compound: Oil-soluble azo polymerization initiator (VR-110 manufactured by FUJIFILM Wako Pure Chemical Corporation)

### <Others>

### (Styrenic Polymer)

Styrenic polymer 1: Styrene/isobutylene/styrenic triblock copolymer (SIBSTAR073T manufactured by Kaneka Corporation, number average molecular weight: 66,000)
Styrenic polymer 2: Hydrogenated methylstyrene (ethylene/butylene) methylstyrene copolymer (SEPTON V9827 manufactured by Kuraray Co., Ltd., weight average molecular weight: 92000)

### (Flame Retardant)

Flame retardant 1: Aromatic condensed phosphoric acid ester compound (PX-200 manufactured by DAIHACHI CHEMICAL INDUSTRY CO., LTD.)
Flame retardant 2: Phosphinic acid metal salt-based flame retardant (Exolit OP-935 manufactured by Clariant Japan K.K.)
Flame retardant 3: Bromine-based flame retardant (SAYTEX8010 manufactured by Albemarle Japan Corporation)

### (Preparation Method)

First, the respective components other than the inorganic filler were added to and mixed in toluene at the compositions (parts by mass) presented in Tables 1 and 2. The mixture was stirred for 60 minutes. Thereafter, the filler (parts by mass) was added to the obtained liquid, and the amount of toluene added was adjusted so that the solid concentration in the resin composition after dispersion was 65 parts by mass, and then the mixture was stirred for 60 minutes to perform primary dispersion of the filler. Thereafter, secondary dispersion of the inorganic filler was performed using a bead mill, thereby obtaining a varnish-like resin composition (varnish).

Next, an evaluation substrate (cured product of prepreg) was obtained as follows.

The obtained varnish was impregnated into a fibrous base material (glass cloth: #1078 type, L glass manufactured by Asahi Kasei Corporation) and then heated and dried at 120° C. for 3 minutes, thereby fabricating a prepreg. Then, 1, 2, and 4 sheets of each of the obtained prepregs were stacked, and both sides of each of the stacked bodies were laminated with copper foil (“FV-WS” manufactured by The Furukawa Electric Co., Ltd., copper foil thickness: 35 μm), heating to a temperature of 200° C. was performed at a rate of temperature increase of 4° C./min, and hot pressing was performed at 200° C. for 120 minutes at a pressure of 3 MPa, thereby fabricating a copper-clad laminate having a thickness of 500 μm.

### Test Example 1

Cured products of prepregs having three different thicknesses were used in the measurement of thermal conductivity described below, and one (cured product of prepreg) prepared by removing the copper foil from a copper-clad laminate obtained by stacking 4 sheets of prepreg was used in the evaluation tests of dielectric properties (relative dielectric constant) and moldability. For the varnish viscosity, a resin varnish was used.

Each evaluation sample prepared as described above was subjected to evaluation by the following methods.

### [Dielectric Properties (Relative Dielectric Constant)]

The relative dielectric constant (Dk) of the evaluation substrate (cured product of prepreg) at 10 GHz was measured by the cavity resonator perturbation method. Specifically, the dielectric loss tangent of the evaluation substrate at 10 GHz was measured using a network analyzer (N5230A manufactured by Keysight Technologies). The pass criterion in the present Example was Dk<4.0.

### [Moldability]

The evaluation substrate fabricated as above was subjected to cross section observation to examine the presence or absence of voids and blurs using a scanning electron microscope (S-3000N manufactured by Hitachi High-Tech Fielding Corporation), and an evaluation substrate not having voids or blurs was taken as the criterion of pass (◯) and an evaluation substrate having voids or blurs was regarded as failure (x).

Furthermore, copper-clad laminates having a thickness of 500 μm were fabricated under different conditions from the above, heating to 200° C. at temperature increase of 2° C./min, holding at 200° C. for 120 minutes, and hot pressing at 3 MPa, and in the same manner as above, an evaluation substrate not having voids or blurs was taken as the criterion of pass (◯) and an evaluation substrate having voids or blurs was regarded as failure (x).

The moldability was evaluated to be “greatly favorable” when an evaluation substrate fabricated under the former condition and an evaluation substrate fabricated under the latter condition were both did not have voids or blurs, the moldability was evaluated to be “favorable” when only an evaluation substrate fabricated under the former condition did not have voids or blurs, and the moldability was evaluated as “failure” when an evaluation substrate fabricated under the former condition and an evaluation substrate fabricated under the latter condition were both had voids or blurs.

### [Varnish Viscosity]

On a PET film, 2 ml of the resin varnish obtained above was dropped. The varnish viscosity was evaluated by measuring the time from when the varnish was dropped on the film until the varnish spread on the film to a thickness of 1 μm or less at that time. As for the evaluation criteria, a resin varnish that spread within 10 seconds was evaluated as pass (◯), and a resin varnish that did not spread was evaluated as failure (x).

### [Thermal Conductivity]

The thermal conductivity of the obtained evaluation substrate (cured product of prepreg) was measured by a method conforming to ASTM D5470. Specifically, the thermal conductivity of the obtained evaluation substrates (cured products obtained by stacking 1, 2, and 4 sheets of prepreg) was measured using a thermal property evaluation instrument (T3Ster DynTIM Tester manufactured by Mentor Graphics Corporation). The pass criterion for thermal conductivity in the present Example was 1.0 W/m. K or more.

The results of the respective evaluations are presented in Tables 1 and 2.

TABLE 1

| | | | Exam- | Exam- | Exam- | Exam- | Exam- | Exam- | Exam- | Exam- | Exam- | Exam- |
|---|---|---|---|---|---|---|---|---|---|---|---|---|
| | | | ple 1 | ple 2 | ple 3 | ple 4 | ple 5 | ple 6 | ple 7 | ple 8 | ple 9 | ple 10 |
| Organic | Radical | PPE1 | 100 | | 90 | 70 | 50 | 70 | 70 | | 70 | 70 |
| resin | polymerizable | PPE2 | | | | | | | | 70 | | |
| component | compound (A) | Bismaleimide | | 100 | | | | | | | | |
| (parts by | | TAIC | | | 10 | 30 | 50 | 30 | 30 | 30 | | 30 |
| mass) | | DVB | | | | | | | | | 30 | |
| | Reaction | Organic peroxide | 1 | 1 | | 1 | | 1 | | 1 | 1 | 1 |
| | initiator (D) | Azo compound | | | | | | | 1 | | | |
| | Thermoplastic | Styrenic polymer 1 | | | | | | | | | | |
| | resin | Styrenic polymer 2 | | | | | | | | | | |
| | Free radical | Free radical | 0.02 | 0.02 | 0.02 | 0.02 | 0.02 | 0.02 | 0.02 | 0.02 | 0.02 | |
| | compound (C) | compound 1 | | | | | | | | | | |
| | | Free radical | | | | | | | | | | 0.02 |
| | | compound 2 | | | | | | | | | | |
| | | Free radical | | | | | | | | | | |
| | | compound 3 | | | | | | | | | | |
| | | Free radical | | | | | | | | | | |
| | | compound 4 | | | | | | | | | | |
| Inorganic | Boron | Boron nitride 1 | 90 | 90 | 90 | 90 | 90 | 45 | 90 | 90 | 90 | 90 |
| filler (B) | nitride (B-1) | Boron nitride 2 | | | | | | | | | | |
| | | Boron nitride 3 | | | | | | 45 | | | | |
| | | Boron nitride 4 | | | | | | | | | | |
| | | Boron nitride 5 | | | | | | | | | | |
| | Silica (B-2) | Silica | 150 | 150 | 150 | 150 | 150 | 150 | 150 | 150 | 150 | 150 |
| | Alumina | Alumina | | | | | | | | | | |
| | Synthetic | Synthetic | | | | | | | | | | |
| | magnesite | magnesite | | | | | | | | | | |
| Flame | P-based flame | Flame | | | | | | | | | | |
| retardant | retardant | retardant 1 | | | | | | | | | | |
| | P-based flame | Flame | | | | | | | | | | |
| | retardant | retardant 2 | | | | | | | | | | |
| | Br-based flame | Flame | | | | | | | | | | |
| | retardant | retardant 3 | | | | | | | | | | |

| | | | | | | | | | | | |
|---|---|---|---|---|---|---|---|---|---|---|---|
| Evaluation | Dielectric properties (Dk) | 3.3 | 3.5 | 3.3 | 3.3 | 3.3 | 3.3 | 3.3 | 3.4 | 3.3 | 3.3 |
| | Moldability condition (1) (when | ◯ | ◯ | ◯ | ◯ | ◯ | ◯ | ◯ | ◯ | ◯ | ◯ |
| | molded at rate of temperature | | | | | | | | | | |
| | increase of 4° C.) | | | | | | | | | | |
| | Moldability condition (2) (when | X | X | X | ◯ | ◯ | ◯ | ◯ | ◯ | ◯ | ◯ |
| | molded at rate of temperature | | | | | | | | | | |
| | increase of 2° C.) | | | | | | | | | | |
| | Varnish viscosity | ◯ | ◯ | ◯ | ◯ | ◯ | ◯ | ◯ | ◯ | ◯ | ◯ |
| | Thermal conductivity | 1.1 | 1.3 | 1.1 | 1.2 | 1.3 | 1.2 | 1.2 | 1.2 | 1.2 | 1.2 |

| | | | Exam- | Exam- | Exam- | Exam- | Exam- | Exam- | Exam- | Exam- |
|---|---|---|---|---|---|---|---|---|---|---|
| | | | ple 11 | ple 12 | ple 13 | ple 14 | ple 15 | ple 16 | ple 17 | ple 18 |
| Organic | Radical | PPE1 | 70 | 70 | 70 | 70 | 70 | 70 | 70 | 70 |
| resin | polymerizable | PPE2 | | | | | | | | |
| component | compound (A) | Bismaleimide | | | | | | | | |
| (parts by | | TAIC | 30 | 30 | 30 | 30 | 30 | 30 | 30 | 30 |
| mass) | | DVB | | | | | | | | |
| | Reaction | Organic peroxide | 1 | 1 | 1 | 1 | 1 | 1 | 1 | 1 |
| | initiator (D) | Azo compound | | | | | | | | |
| | Thermoplastic | Styrenic polymer 1 | | | | | | | | |
| | resin | Styrenic polymer 2 | | | | | | | | |
| | Free radical | Free radical | | | 0.01 | 0.05 | 0.1 | 0.02 | 0.02 | 0.02 |
| | compound (C) | compound 1 | | | | | | | | |
| | | Free radical | | | | | | | | |
| | | compound 2 | | | | | | | | |
| | | Free radical | 0.02 | | | | | | | |
| | | compound 3 | | | | | | | | |
| | | Free radical | | 0.02 | | | | | | |
| | | compound 4 | | | | | | | | |
| Inorganic | Boron | Boron nitride 1 | 90 | 90 | 90 | 90 | 90 | 150 | 75 | 50 |
| filler (B) | nitride (B-1) | Boron nitride 2 | | | | | | | | |
| | | Boron nitride 3 | | | | | | | | |
| | | Boron nitride 4 | | | | | | | | |
| | | Boron nitride 5 | | | | | | | | |
| | Silica (B-2) | Silica | 150 | 150 | 150 | 150 | 150 | 90 | 125 | 350 |
| | Alumina | Alumina | | | | | | | | |
| | Synthetic | Synthetic | | | | | | | | |
| | magnesite | magnesite | | | | | | | | |
| Flame | P-based flame | Flame | | | | | | | | |
| retardant | retardant | retardant 1 | | | | | | | | |
| | P-based flame | Flame | | | | | | | | |
| | retardant | retardant 2 | | | | | | | | |
| | Br-based flame | Flame | | | | | | | | |
| | retardant | retardant 3 | | | | | | | | |

| | | | | | | | | | |
|---|---|---|---|---|---|---|---|---|---|
| Evaluation | Dielectric properties (Dk) | 3.3 | 3.3 | 3.3 | 3.3 | 3.3 | 3.3 | 3.2 | 3.5 |
| | Moldability condition (1) (when | ◯ | ◯ | ◯ | ◯ | ◯ | ◯ | ◯ | ◯ |
| | molded at rate of temperature | | | | | | | | |
| | increase of 4° C.) | | | | | | | | |
| | Moldability condition (2) (when | ◯ | ◯ | X | ◯ | ◯ | ◯ | ◯ | ◯ |
| | molded at rate of temperature | | | | | | | | |
| | increase of 2° C.) | | | | | | | | |
| | Varnish viscosity | ◯ | ◯ | ◯ | ◯ | ◯ | ◯ | ◯ | ◯ |
| | Thermal conductivity | 1.2 | 1.2 | 1.2 | 1.2 | 1.2 | 1.8 | 1 | 1 |

TABLE 2

| | | | Exam- | Exam- | Exam- | Exam- | Exam- | Exam- | Exam- | Exam- | Exam- | Exam- |
|---|---|---|---|---|---|---|---|---|---|---|---|---|
| | | | ple 19 | ple 20 | ple 21 | ple 22 | ple 23 | ple 24 | ple 25 | ple 26 | ple 27 | ple 28 |
| Organic | Radical | PPE1 | 70 | 70 | 70 | 70 | 70 | 70 | 70 | 63 | 63 | 70 |
| resin | polymerizable | PPE2 | | | | | | | | | | |
| component | compound (A) | Bismaleimide | | | | | | | | | | |
| (parts by | | TAIC | 30 | 30 | 30 | 30 | 30 | 30 | 30 | 27 | 27 | 30 |
| mass) | | DVB | | | | | | | | | | |
| | Reaction | Organic peroxide | 1 | 1 | 1 | 1 | 1 | 1 | 1 | 1 | 1 | 1 |
| | initiator (D) | Azo compound | | | | | | | | | | |
| | Thermoplastic | Styrenic polymer 1 | | | | | | | | 10 | | |
| | resin | Styrenic polymer 2 | | | | | | | | | 10 | |
| | Free radical | Free radical | 0.02 | 0.1 | 0.02 | 0.02 | 0.02 | 0.02 | 0.02 | 0.02 | 0.02 | 0.02 |
| | compound (C) | compound 1 | | | | | | | | | | |
| | | Free radical | | | | | | | | | | |
| | | compound 2 | | | | | | | | | | |
| | | Free radical | | | | | | | | | | |
| | | compound 3 | | | | | | | | | | |
| | | Free radical | | | | | | | | | | |
| | | compound 4 | | | | | | | | | | |
| Inorganic | Boron | Boron nitride 1 | 50 | 50 | 50 | 100 | 90 | 90 | 90 | 90 | 90 | |
| filler (B) | nitride (B-1) | Boron nitride 2 | | | | | | | | | | 90 |
| | | Boron nitride 3 | | | | | | | | | | |
| | | Boron nitride 4 | | | | | | | | | | |
| | | Boron nitride 5 | | | | | | | | | | |
| | Silica (B-2) | Silica | 200 | 200 | 200 | 350 | 150 | 150 | 150 | 150 | 150 | 150 |
| | Alumina | Alumina | 150 | 150 | | | | | | | | |
| | Synthetic | Synthetic | | | 100 | | | | | | | |
| | magnesite | magnesite | | | | | | | | | | |
| Flame | P-based flame | Flame | | | | | 15 | | | | | |
| retardant | retardant | retardant 1 | | | | | | | | | | |
| | P-based flame | Flame | | | | | | 15 | | | | |
| | retardant | retardant 2 | | | | | | | | | | |
| | Br-based flame | Flame | | | | | | | 15 | | | |
| | retardant | retardant 3 | | | | | | | | | | |

| | | | | | | | | | | | |
|---|---|---|---|---|---|---|---|---|---|---|---|
| Evaluation | Dielectric properties (Dk) | 3.8 | 3.8 | 3.6 | 3.5 | 3.3 | 3.3 | 3.3 | 3.3 | 3.3 | 3.3 |
| | Moldability condition (1) (when | ◯ | ◯ | ◯ | ◯ | ◯ | ◯ | ◯ | ◯ | ◯ | ◯ |
| | molded at rate of temperature | | | | | | | | | | |
| | increase of 4° C.) | | | | | | | | | | |
| | Moldability condition (2) (when | ◯ | ◯ | ◯ | X | ◯ | ◯ | ◯ | ◯ | ◯ | ◯ |
| | molded at rate of temperature | | | | | | | | | | |
| | increase of 2° C.) | | | | | | | | | | |
| | Varnish viscosity | ◯ | ◯ | ◯ | ◯ | ◯ | ◯ | ◯ | ◯ | ◯ | ◯ |
| | Thermal conductivity | 1.3 | 1.3 | 1.2 | 1.2 | 1.1 | 1 | 1.0 | 1.2 | 1.2 | 1.2 |

| | | | | | | Compar- | Compar- | Compar- | Compar- |
|---|---|---|---|---|---|---|---|---|---|
| | | | | | | ative | ative | ative | ative |
| | | | Exam- | Exam- | Exam- | Exam- | Exam- | Exam- | Exam- |
| | | | ple 29 | ple 30 | ple 31 | ple 1 | ple 2 | ple 3 | ple 4 |
| Organic | Radical | PPE1 | 70 | 70 | 70 | 70 | 70 | 70 | 70 |
| resin | polymerizable | PPE2 | | | | | | | |
| component | compound (A) | Bismaleimide | | | | | | | |
| (parts by | | TAIC | 30 | 30 | 30 | 30 | 30 | 30 | 30 |
| mass) | | DVB | | | | | | | |
| | Reaction | Organic peroxide | 1 | 1 | 1 | 1 | 1 | 1 | 1 |
| | initiator (D) | Azo compound | | | | | | | |
| | Thermoplastic | Styrenic polymer 1 | | | | | | | |
| | resin | Styrenic polymer 2 | | | | | | | |
| | Free radical | Free radical | 0.02 | 0.02 | 0.02 | | 0.02 | 0.02 | 0.02 |
| | compound (C) | compound 1 | | | | | | | |
| | | Free radical | | | | | | | |
| | | compound 2 | | | | | | | |
| | | Free radical | | | | | | | |
| | | compound 3 | | | | | | | |
| | | Free radical | | | | | | | |
| | | compound 4 | | | | | | | |
| Inorganic | Boron | Boron nitride 1 | | | | 100 | 0 | 90 | |
| filler (B) | nitride (B-1) | Boron nitride 2 | | | | | | | |
| | | Boron nitride 3 | 90 | | | | | | |
| | | Boron nitride 4 | | 90 | | | | | 200 |
| | | Boron nitride 5 | | | 90 | | | | |
| | Silica (B-2) | Silica | 150 | 150 | 150 | 300 | 400 | | 0 |
| | Alumina | Alumina | | | | | | 250 | |
| | Synthetic | Synthetic | | | | | | | |
| | magnesite | magnesite | | | | | | | |
| Flame | P-based flame | Flame | | | | | | | |
| retardant | retardant | retardant 1 | | | | | | | |
| | P-based flame | Flame | | | | | | | |
| | retardant | retardant 2 | | | | | | | |
| | Br-based flame | Flame | | | | | | | |
| | retardant | retardant 3 | | | | | | | |

| | | | | | | | | |
|---|---|---|---|---|---|---|---|---|
| Evaluation | Dielectric properties (Dk) | 3.3 | 3.3 | 3.3 | 3.4 | 3.4 | 4.2 | — |
| | Moldability condition (1) (when | ◯ | ◯ | ◯ | X | ◯ | ◯ | X |
| | molded at rate of temperature | | | | | | | |
| | increase of 4° C.) | | | | | | | |
| | Moldability condition (2) (when | ◯ | ◯ | ◯ | X | X | ◯ | X |
| | molded at rate of temperature | | | | | | | |
| | increase of 2° C.) | | | | | | | |
| | Varnish viscosity | ◯ | ◯ | ◯ | ◯ | ◯ | ◯ | X |
| | Thermal conductivity | 1.2 | 1.3 | 1.4 | 1.1 | 0.9 | 1.3 | — |

### (Discussion)

As can be seen from Table 1, in Examples in which the resin compositions of the present invention were used, it has been found that it is possible to provide a resin composition that can provide a cured product exhibiting low dielectric properties (relative dielectric constant) and a high thermal conductivity, can secure the varnish viscosity necessary for molding, and exhibits moldability.

On the other hand, as presented in Table 2, it was not possible to obtain sufficient moldability in Comparative Example 1 relating to a resin composition that did not contain a free radical compound. Comparative Example 2, in which boron nitride was not used as an inorganic filler, was inferior in thermal conductivity. In Comparative Example 3, in which alumina was used as an inorganic filler instead of silica, the relative dielectric constant was high. In Comparative Example 4, in which only boron nitride was used as an inorganic filler, the varnish viscosity necessary for molding was not obtained and it was not possible to fabricate an evaluation sample (the varnish was not impregnated into the base material).

### Test Example 2

Regarding the evaluation samples of Examples, the following dielectric loss tangent was also measured as dielectric properties.

### [Dielectric Properties (Dielectric Loss Tangent)]

The dielectric loss tangent (Df) of the evaluation substrate (cured product of prepreg) at 10 GHz was measured by the cavity resonator perturbation method. Specifically, the dielectric loss tangent of the evaluation substrate at 10 GHz was measured using a network analyzer (N5230A manufactured by Keysight Technologies). The results are presented in Tables 3 and 4.

TABLE 3

| | | | Exam- | Exam- | Exam- | Exam- | Exam- | Exam- | Exam- | Exam- |
|---|---|---|---|---|---|---|---|---|---|---|
| | | | ple 1 | ple 2 | ple 3 | ple 4 | ple 5 | ple 6 | ple 7 | ple 8 |
| Organic | Radical | PPE1 | 100 | | 90 | 70 | 50 | 70 | 70 | |
| resin | polymerizable | PPE2 | | | | | | | | 70 |
| component | compound (A) | Bismaleimide | | 100 | | | | | | |
| (parts by | | TAIC | | | 10 | 30 | 50 | 30 | 30 | 30 |
| mass) | | DVB | | | | | | | | |
| | Reaction | Organic peroxide | 1 | 1 | | 1 | | 1 | | 1 |
| | initiator (D) | Azo compound | | | | | | | 1 | |
| | Thermoplastic | Styrenic | | | | | | | | |
| | resin | polymer 1 | | | | | | | | |
| | | Styrenic | | | | | | | | |
| | | polymer 2 | | | | | | | | |
| | Free radical | Free radical | 0.02 | 0.02 | 0.02 | 0.02 | 0.02 | 0.02 | 0.02 | 0.02 |
| | compound (C) | compound 1 | | | | | | | | |
| | | Free radical | | | | | | | | |
| | | compound 2 | | | | | | | | |
| | | Free radical | | | | | | | | |
| | | compound 3 | | | | | | | | |
| | | Free radical | | | | | | | | |
| | | compound 4 | | | | | | | | |
| Inorganic | Boron | Boron nitride 1 | 90 | 90 | 90 | 90 | 90 | 45 | 90 | 90 |
| filler (B) | nitride (B-1) | Boron nitride 2 | | | | | | | | |
| | | Boron nitride 3 | | | | | | 45 | | |
| | | Boron nitride 4 | | | | | | | | |
| | | Boron nitride 5 | | | | | | | | |
| | Silica (B-2) | Silica | 150 | 150 | 150 | 150 | 150 | 150 | 150 | 150 |
| | Alumina | Alumina | | | | | | | | |
| | Synthetic | Synthetic | | | | | | | | |
| | magnesite | magnesite | | | | | | | | |
| Flame | P-based flame | Flame | | | | | | | | |
| retardant | retardant | retardant 1 | | | | | | | | |
| | P-based flame | Flame | | | | | | | | |
| | retardant | retardant 2 | | | | | | | | |
| | Br-based flame | Flame | | | | | | | | |
| | retardant | retardant 3 | | | | | | | | |

| | | | | | | | | | |
|---|---|---|---|---|---|---|---|---|---|
| Evaluation | Dielectric properties (Df) | 0.0017 | 0.0028 | 0.0017 | 0.0018 | 0.002 | 0.0018 | 0.0017 | 0.0017 |

| | | | Exam- | Exam- | Exam- | Exam- | Exam- | Exam- | Exam- | Exam- |
|---|---|---|---|---|---|---|---|---|---|---|
| | | | ple 9 | ple 10 | ple 11 | ple 12 | ple 13 | ple 14 | ple 15 | ple 16 |
| Organic | Radical | PPE1 | 70 | 70 | 70 | 70 | 70 | 70 | 70 | 70 |
| resin | polymerizable | PPE2 | | | | | | | | |
| component | compound (A) | Bismaleimide | | | | | | | | |
| (parts by | | TAIC | | 30 | 30 | 30 | 30 | 30 | 30 | 30 |
| mass) | | DVB | 30 | | | | | | | |
| | Reaction | Organic peroxide | 1 | 1 | 1 | 1 | 1 | 1 | 1 | 1 |
| | initiator (D) | Azo compound | | | | | | | | |
| | Thermoplastic | Styrenic | | | | | | | | |
| | resin | polymer 1 | | | | | | | | |
| | | Styrenic | | | | | | | | |
| | | polymer 2 | | | | | | | | |
| | Free radical | Free radical | 0.02 | | | | 0.01 | 0.05 | 0.1 | 0.02 |
| | compound (C) | compound 1 | | | | | | | | |
| | | Free radical | | 0.02 | | | | | | |
| | | compound 2 | | | | | | | | |
| | | Free radical | | | 0.02 | | | | | |
| | | compound 3 | | | | | | | | |
| | | Free radical | | | | 0.02 | | | | |
| | | compound 4 | | | | | | | | |
| Inorganic | Boron | Boron nitride 1 | 90 | 90 | 90 | 90 | 90 | 90 | 90 | 150 |
| filler (B) | nitride (B-1) | Boron nitride 2 | | | | | | | | |
| | | Boron nitride 3 | | | | | | | | |
| | | Boron nitride 4 | | | | | | | | |
| | | Boron nitride 5 | | | | | | | | |
| | Silica (B-2) | Silica | 150 | 150 | 150 | 150 | 150 | 150 | 150 | 90 |
| | Alumina | Alumina | | | | | | | | |
| | Synthetic | Synthetic | | | | | | | | |
| | magnesite | magnesite | | | | | | | | |
| Flame | P-based flame | Flame | | | | | | | | |
| retardant | retardant | retardant 1 | | | | | | | | |
| | P-based flame | Flame | | | | | | | | |
| | retardant | retardant 2 | | | | | | | | |
| | Br-based flame | Flame | | | | | | | | |
| | retardant | retardant 3 | | | | | | | | |

| | | | | | | | | | |
|---|---|---|---|---|---|---|---|---|---|
| Evaluation | Dielectric properties (Df) | 0.0018 | 0.0018 | 0.0018 | 0.0018 | 0.0017 | 0.002 | 0.0021 | 0.0017 |

TABLE 4

| | | | Exam- | Exam- | Exam- | Exam- | Exam- | Exam- | Exam- | Exam- |
|---|---|---|---|---|---|---|---|---|---|---|
| | | | ple 17 | ple 18 | ple 19 | ple 20 | ple 21 | ple 22 | ple 23 | ple 24 |
| Organic | Radical | PPE1 | 70 | 70 | 70 | 70 | 70 | 70 | 70 | 70 |
| resin | polymerizable | PPE2 | | | | | | | | |
| component | compound (A) | Bismaleimide | | | | | | | | |
| (parts by | | TAIC | 30 | 30 | 30 | 30 | 30 | 30 | 30 | 30 |
| mass) | | DVB | | | | | | | | |
| | Reaction | Organic peroxide | 1 | 1 | 1 | 1 | 1 | 1 | 1 | 1 |
| | initiator (D) | Azo compound | | | | | | | | |
| | Thermoplastic | Styrenic | | | | | | | | |
| | resin | polymer 1 | | | | | | | | |
| | | Styrenic | | | | | | | | |
| | | polymer 2 | | | | | | | | |
| | Free radical | Free radical | 0.02 | 0.02 | 0.02 | 0.1 | 0.02 | 0.02 | 0.02 | 0.02 |
| | compound (C) | compound 1 | | | | | | | | |
| | | Free radical | | | | | | | | |
| | | compound 2 | | | | | | | | |
| | | Free radical | | | | | | | | |
| | | compound 3 | | | | | | | | |
| | | Free radical | | | | | | | | |
| | | compound 4 | | | | | | | | |
| Inorganic | Boron | Boron nitride 1 | 75 | 50 | 50 | 50 | 50 | 100 | 90 | 90 |
| filler (B) | nitride (B-1) | Boron nitride 2 | | | | | | | | |
| | | Boron nitride 3 | | | | | | | | |
| | | Boron nitride 4 | | | | | | | | |
| | | Boron nitride 5 | | | | | | | | |
| | Silica (B-2) | Silica | 125 | 350 | 200 | 200 | 200 | 350 | 150 | 150 |
| | Alumina | Alumina | | | 150 | 150 | | | | |
| | Synthetic | Synthetic | | | | | 100 | | | |
| | magnesite | magnesite | | | | | | | | |
| Flame | P-based flame | Flame | | | | | | | 15 | |
| retardant | retardant | retardant 1 | | | | | | | | |
| | P-based flame | Flame | | | | | | | | 15 |
| | retardant | retardant 2 | | | | | | | | |
| | Br-based flame | Flame | | | | | | | | |
| | retardant | retardant 3 | | | | | | | | |

| | | | | | | | | | |
|---|---|---|---|---|---|---|---|---|---|
| Evaluation | Dielectric properties (Df) | 0.0017 | 0.0022 | 0.0026 | 0.003 | 0.0025 | 0.0023 | 0.0016 | 0.0019 |

| | | | Exam- | Exam- | Exam- | Exam- | Exam- | Exam- | Exam- |
|---|---|---|---|---|---|---|---|---|---|
| | | | ple 25 | ple 26 | ple 27 | ple 28 | ple 29 | ple 30 | ple 31 |
| Organic | Radical | PPE1 | 70 | 63 | 63 | 70 | 70 | 70 | 70 |
| resin | polymerizable | PPE2 | | | | | | | |
| component | compound (A) | Bismaleimide | | | | | | | |
| (parts by | | TAIC | 30 | 27 | 27 | 30 | 30 | 30 | 30 |
| mass) | | DVB | | | | | | | |
| | Reaction | Organic peroxide | 1 | 1 | 1 | 1 | 1 | 1 | 1 |
| | initiator (D) | Azo compound | | | | | | | |
| | Thermoplastic | Styrenic | | 10 | | | | | |
| | resin | polymer 1 | | | | | | | |
| | | Styrenic | | | 10 | | | | |
| | | polymer 2 | | | | | | | |
| | Free radical | Free radical | 0.02 | 0.02 | 0.02 | 0.02 | 0.02 | 0.02 | 0.02 |
| | compound (C) | compound 1 | | | | | | | |
| | | Free radical | | | | | | | |
| | | compound 2 | | | | | | | |
| | | Free radical | | | | | | | |
| | | compound 3 | | | | | | | |
| | | Free radical | | | | | | | |
| | | compound 4 | | | | | | | |
| Inorganic | Boron | Boron nitride 1 | 90 | 90 | 90 | | | | |
| filler (B) | nitride (B-1) | Boron nitride 2 | | | | 90 | | | |
| | | Boron nitride 3 | | | | | 90 | | |
| | | Boron nitride 4 | | | | | | 90 | |
| | | Boron nitride 5 | | | | | | | 90 |
| | Silica (B-2) | Silica | 150 | 150 | 150 | 150 | 150 | 150 | 150 |
| | Alumina | Alumina | | | | | | | |
| | Synthetic | Synthetic | | | | | | | |
| | magnesite | magnesite | | | | | | | |
| Flame | P-based flame | Flame | | | | | | | |
| retardant | retardant | retardant 1 | | | | | | | |
| | P-based flame | Flame | | | | | | | |
| | retardant | retardant 2 | | | | | | | |
| | Br-based flame | Flame | 15 | | | | | | |
| | retardant | retardant 3 | | | | | | | |

| | | | | | | | | |
|---|---|---|---|---|---|---|---|---|
| Evaluation | Dielectric properties (Df) | 0.0018 | 0.0018 | 0.0018 | 0.0018 | 0.0018 | 0.0018 | 0.0018 |

As presented in Tables 3 and 4, it has been found that all the samples of Examples in which the resin compositions of the present invention are used exhibit low dielectric properties as the dielectric loss tangent is Df≤0.003.

This application is based on Japanese Patent Application No. 2021-210990 filed on Dec. 24, 2021, and the contents of which are included in the present application.

In order to express the present invention, the present invention has been described above appropriately and sufficiently through the embodiments with reference to specific examples, drawings and the like. However, it should be recognized by those skilled in the art that changes and/or improvements of the above-described embodiments can be readily made. Accordingly, changes or improvements made by those skilled in the art shall be construed as being included in the scope of the claims unless otherwise the changes or improvements are at the level which departs from the scope of the appended claims.

### INDUSTRIAL APPLICABILITY

The present invention has wide industrial applicability in technical fields such as electronic materials, electronic devices, and optical devices.

1. A resin composition comprising:
a radical polymerizable compound (A);
an inorganic filler (B) containing boron nitride (B-1) and silica (B-2); and
a free radical compound (C) having at least one free radical group selected from the group consisting of structures represented by the following Formulas (1), (2), (3) and (4) in a molecule.

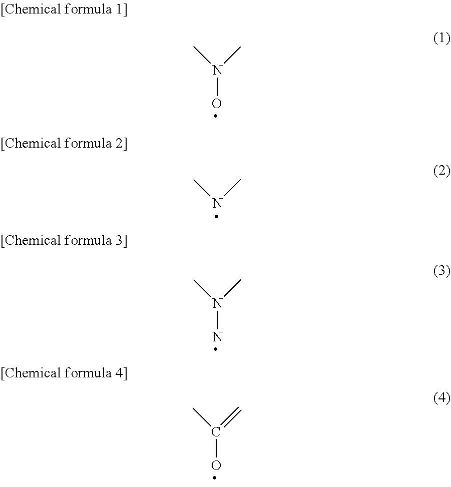

2. The resin composition according to claim 1, wherein a total content of boron nitride (B-1) and silica (B-2) in the resin composition is 200 to 500 mass % with respect to a total solid amount in the resin composition.

3. The resin composition according to claim 1, wherein a content of the boron nitride (B-1) is 10 to 80 parts by mass with respect to 100 parts by mass of a sum of boron nitride (B-1) and silica (B-2).

4. The resin composition according to claim 1, wherein
the free radical compound (C) includes at least one compound selected from the following Formulas (17) to (19): 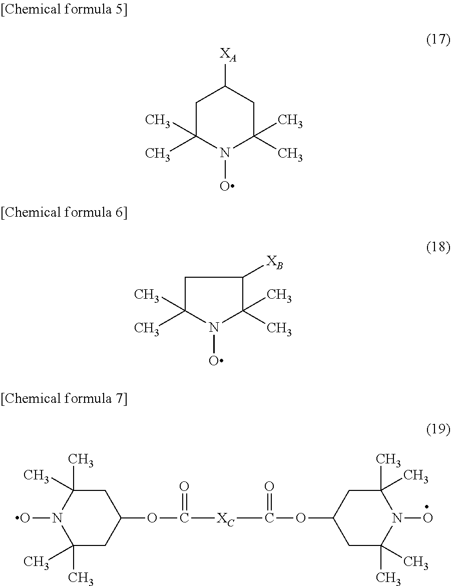
(in Formulas (17) and (18), X_{A} and X_{B} each independently represent a hydrogen atom, an amino group, a cyano group, a hydroxy group, an isothiocyanate, a methoxy group, a carboxy group, a carbonyl group, an amide group, a benzoyloxy group, or an ether bond, and in Formula (19), X_{C} represents an alkylene group, an aromatic structure, a carbonyl group, an amide group, or an ether bond).

5. The resin composition according to claim 1, wherein the radical polymerizable compound (A) includes at least one selected from the group consisting of a polyphenylene ether compound (A-1) having a carbon-carbon unsaturated double bond in a molecule, a hydrocarbon-based compound (A-2) having a carbon-carbon unsaturated double bond in a molecule, and a maleimide compound (A-3).

6. The resin composition according to claim 1, further comprising a reaction initiator (D).

7. The resin composition according to claim 1, wherein a content of the free radical compound (C) is 0.01 to 0.1 parts by mass with respect to 100 parts by mass of the radical polymerizable compound (A).

8. The resin composition according to claim 6, wherein a content of the free radical compound (C) is 0.5 to 10 parts by mass with respect to 100 parts by mass of a sum of the free radical compound (C) and the reaction initiator (D).

9. The resin composition according to claim 1, wherein the boron nitride (B-1) includes at least one or more kinds of boron nitrides having an average particle size of 0.5 to 30 μm.

10. The resin composition according to claim 1, further comprising a flame retardant.

11. The resin composition according to claim 1, wherein a cured product of the resin composition has a thermal conductivity of 1.0 W/m·K or more and a relative dielectric constant of 4.0 or less at a frequency of 10 GHz.

12. A prepreg comprising:
the resin composition according to any one of claims 1 to 11 or a semi-cured product of the resin composition; and
a fibrous base material.

13. A film with resin comprising:
a resin layer containing the resin composition according to any one of claims 1 to 11 or a semi-cured product of the resin composition; and
a support film.

14. A metal foil with resin comprising:
a resin layer containing the resin composition according to any one of claims 1 to 11 or a semi-cured product of the resin composition; and
a metal foil.

15. A metal-clad laminate comprising:
an insulating layer containing a cured product of the resin composition according to any one of claims 1 to 11; and
a metal foil.

16. A wiring board comprising:
an insulating layer containing a cured product of the resin composition according to any one of claims 1 to 11; and
a wiring.

17. A metal-clad laminate comprising:
an insulating layer containing a cured product of the prepreg according to claim 12; and
a metal foil.

18. A wiring board comprising:
an insulating layer containing a cured product of the prepreg according to claim 12; and
a wiring.
